(19) United States
(12) Patent Application Publication
(10) Pub. No.: US 2024/0125931 A1
(43) Pub. Date: Apr. 18, 2024

(54) LIGHT RECEIVING DEVICE, DISTANCE MEASURING DEVICE, AND SIGNAL PROCESSING METHOD IN LIGHT RECEIVING DEVICE

(71) Applicant: SONY SEMICONDUCTOR SOLUTIONS CORPORATION, KANAGAWA (JP)

(72) Inventors: HIROAKI SAKAGUCHI, KANAGAWA (JP); KOICHI HASEGAWA, KANAGAWA (JP)

(21) Appl. No.: 18/264,465

(22) PCT Filed: Jan. 26, 2022
(86) PCT No.: PCT/JP2022/002755

§ 371 Date: Aug. 7, 2023

(30) Foreign Application Priority Data
Feb. 18, 2021 (JP) 2021-023924

(51) Int. Cl. G01S 17/10; G01S 7/4863; G01S 7/4865

(52) U.S. Cl. CPC G01S 17/10; G01S 7/4863; G01S 7/4865

(57) ABSTRACT

A light receiving device (20) according to one aspect of the present disclosure includes: a light receiving section (22) including a plurality of photon-counting light receiving elements that receives reflected light from a distance measurement target (40) based on irradiation pulsed light from a light source section (10); a selecting section (23) that selects individual detection values of the plurality of light receiving elements at a predetermined time; an addition section (24) that generates 2^{N}−1 binary values (N is a positive integer) from the individual detection values of the plurality of light receiving elements at the predetermined time selected by the selecting section (23) and that calculates an N-bit pixel value by adding up all the 2^{N}−1 binary values; and
a computing section (26) that performs computation related to distance measurement using the N-bit pixel value calculated by the addition section (24).

### FIELD

The present disclosure relates to a light receiving device, a distance measuring device, and a signal processing method in the light receiving device.

### BACKGROUND

In recent years, a Time of Flight sensor (ToF sensor) has attracted attention as a distance measuring device that measures a distance by a ToF method. For example, there is a ToF sensor that measures a distance to a distance measurement target using a plurality of single photon avalanche diode (SPAD) elements formed by a complementary metal oxide semiconductor (CMOS) semiconductor integrated circuit technology and arranged with a planar arrangement (refer to Patent Literatures 1 and 2, for example).

The ToF sensor measures the time from the light emission by the light source to the incidence of reflected light on the SPAD element (hereinafter, referred to as flight time) a plurality of times as a physical quantity, and specifies the distance to the distance measurement target on the basis of a histogram of the physical quantity generated based on the measurement result. The reflected light from the distance measurement target is diffused, and its intensity is inversely proportional to the square of the distance. Therefore, histograms of reflected light based on a plurality of times of laser emission are accumulated (by cumulative calculation) to improve S/N and enable discrimination of weak reflected light from a distance measurement target in a longer distance.

### CITATION LIST

### Patent Literature

Patent Literature 1: JP 2016-151458 A
Patent Literature 2: JP 2016-161438 A

### SUMMARY

### Technical Problem

In the distance measuring device as described above, one pixel is constituted by n SPAD elements (n=positive integer (natural number)), and a total of detection values of the n SPAD elements is set as a pixel value. In this case, the pixel value ranges from 0 to n, which includes n+1 values. On the other hand, the number of bits required to represent the pixel value is ceil (log 2 (n+1)). Note that the above-described ceil ( ) means a round-up of a decimal number.

For example, in a case where n=8, the number of possible values of the pixel value is 9, which ranges from 0 to 8, and the number of bits required to express the pixel value is 4 bits (4 b). The range that can be expressed by 4 b is a range of sixteen values, that is, 0 to 15. However, only the range (dynamic range) of nine values of 0 to 8 will be actually used, and the other portions of the range will be unnecessary. That is, 4 b is required to just to express the pixel values of 0 to 8.

Usually, one pixel is often constituted on the basis of n, which is set as a power of 2, a square number of a natural number, a multiple thereof, or the like. In a case where n is a power of 2, the number of bits of the pixel value needs to be increased by one bit even though there is a difference of 1 between the range of the pixel value of the pixel including n SPAD elements and the range of the pixel value of the pixel including n−1 SPAD elements. This increases waste of computing elements and wiring lines (such as a computing elements that performs computation using a pixel value and a wiring line for transmitting a pixel value) related to pixel values. This would result in circuit scale expansion and power increase.

In view of this, the present disclosure provides a light receiving device, a distance measuring device, and a signal processing method in the light receiving device capable of achieving circuit scale reduction and power reduction.

### Solution to Problem

A light receiving device according to one aspect of the present disclosure includes: a light receiving section including a plurality of photon-counting light receiving elements that receives reflected light from a distance measurement target based on irradiation pulsed light from a light source section; a selecting section that selects individual detection values of the plurality of light receiving elements at a predetermined time; an addition section that generates 2^{N}−1 binary values (N being a positive integer) from the individual detection values of the plurality of light receiving elements at the predetermined time selected by the selecting section and that calculates an N-bit pixel value by adding up all the 2^{N}−1 binary values; and a computing section that performs computation related to distance measurement using the N-bit pixel value calculated by the addition section.

A distance measuring device according to one aspect of the present disclosure includes: a light source section that irradiates a distance measurement target with pulsed light; and a light receiving device that receives reflected light from the distance measurement target based on irradiation pulsed light from the light source section, wherein the light receiving device includes: a light receiving section including a plurality of photon-counting light receiving elements that receives reflected light from a distance measurement target; a selecting section that selects individual detection values of the plurality of light receiving elements at a predetermined time; an addition section that generates 2^{N}−1 binary values (N being a positive integer) from the individual detection values of the plurality of light receiving elements at the predetermined time selected by the selecting section and that calculates an N-bit pixel value by adding up all the 2^{N}−1 binary values; and a computing section that performs computation related to distance measurement using the N-bit pixel value calculated by the addition section.

A signal processing method to be used by a light receiving device, the method according to one aspect of the present disclosure includes: receiving, by a light receiving section including a plurality of photon-counting light receiving elements, reflected light from a distance measurement target based on irradiation pulsed light from a light source section; selecting individual detection values of the plurality of light receiving elements at a predetermined time; generating 2^{N}−1 binary values (N being a positive integer) from the individual detection values of the plurality of light receiving elements at the predetermined time selected and calculating an N-bit pixel value by adding up all the 2^{N}−1 binary values; and performing computation related to distance measurement using the N-bit pixel value calculated.

### BRIEF DESCRIPTION OF DRAWINGS

FIG. 1 is a diagram depicting an example of a schematic configuration of a distance measuring device according to a first embodiment.

FIG. 2 is a diagram depicting an example of selective addition processing according to the first embodiment.

FIG. 3 is a diagram depicting an example of a schematic configuration of a light receiving section according to the first embodiment.

FIG. 4 is a diagram depicting an example of a schematic configuration of a SPAD array section according to the first embodiment.

FIG. 5 is a diagram depicting an example of a schematic configuration of the SPAD pixel according to the first embodiment.

FIG. 6 is a diagram depicting an example of a schematic configuration of an addition section according to the first embodiment.

FIG. 7 is a diagram depicting an example of a schematic configuration of a histogram processing section according to the first embodiment.

FIG. 8 is a first diagram depicting histogram creation processing according to the first embodiment.

FIG. 9 is a second diagram depicting the histogram creation processing according to the first embodiment.

FIG. 10 is a third diagram depicting the histogram creation processing according to the first embodiment.

FIG. 11 is a diagram depicting a plurality of examples of a rectangular region having 2^{N}−1 SPAD pixels according to the first embodiment.

FIG. 12 is a diagram depicting a first implementation example of selective addition processing according to the first embodiment.

FIG. 13 is a diagram depicting a second implementation example of the selective addition processing according to the first embodiment.

FIG. 14 is a diagram depicting a third implementation example of the selective addition processing according to the first embodiment.

FIG. 15 is a diagram depicting a fourth implementation example of the selective addition processing according to the first embodiment.

FIG. 16 is a diagram depicting a fifth implementation example of the selective addition processing according to the first embodiment.

FIG. 17 is a diagram depicting a sixth implementation example of the selective addition processing according to the first embodiment.

FIG. 18 is a diagram depicting a seventh implementation example of the selective addition processing according to the first embodiment.

FIG. 19 is a diagram depicting an example of a schematic configuration of a distance measuring device according to a second embodiment.

FIG. 20 is a block diagram depicting an example of schematic configuration of a vehicle control system.

FIG. 21 is a diagram of assistance in explaining an example of installation positions of an outside-vehicle information detecting section and an imaging section.

### DESCRIPTION OF EMBODIMENTS

Embodiments of the present disclosure will be described below in detail with reference to the drawings. Note that the device, the method, and the like according to the present disclosure are not limited by this embodiment. Moreover, basically in each of the following embodiments, the same parts are denoted by the same reference symbols, and a repetitive description thereof will be omitted.

One or more embodiments (implementation examples and modifications) described below can each be implemented independently. On the other hand, at least some of the plurality of embodiments described below may be appropriately combined with at least some of other embodiments. The plurality of embodiments may include novel features different from each other. Accordingly, the plurality of embodiments can contribute to achieving or solving different objects or problems, and can exhibit different effects. The effects described in individual embodiments are merely examples, and thus, there may be other effects, not limited to the exemplified effects.

The present disclosure will be described in the following order.
1. First Embodiment
1-1. Schematic configuration example of distance measuring device
1-2. Example of schematic configuration of light receiving section
1-3. Example of schematic configuration of SPAD array section
1-4. Example of schematic configuration of SPAD pixel
1-5. Example of schematic configuration of addition section
1-6. Example of schematic configuration of histogram processing section
1-7. Example of histogram creation processing
1-8. Example of schematic configuration of computing section
1-9. Implementation examples of selective addition processing
1-9-1. First implementation example
1-9-2. Second implementation example
1-9-3. Third implementation example
1-9-4. Fourth implementation example
1-9-5. Fifth implementation example
1-9-6. Sixth implementation example
1-9-7. Seventh implementation example
1-10. Action and effects
2. Second Embodiment
2-1. Schematic configuration example of distance measuring device
2-2. Action and effect
3. Application examples
4. Supplementary notes

### 1. First Embodiment

### 1-1. Schematic Configuration Example of Distance Measuring Device 1

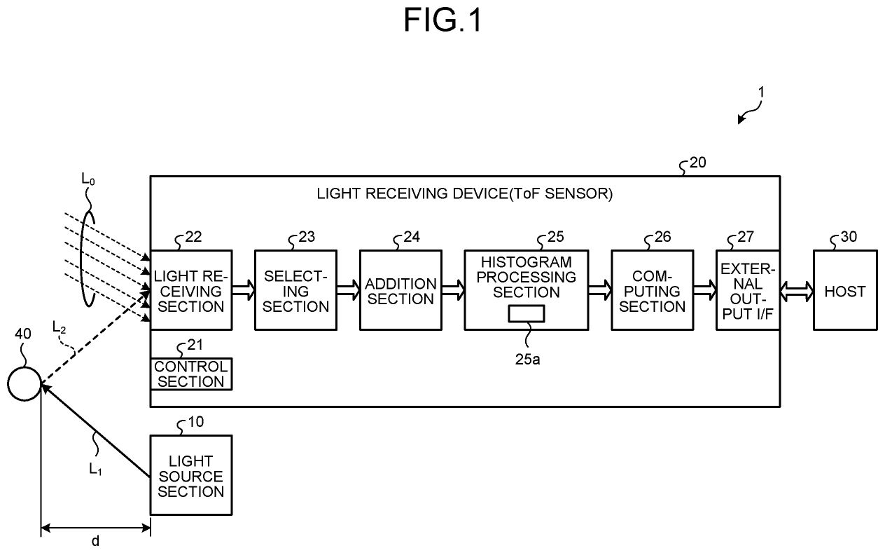

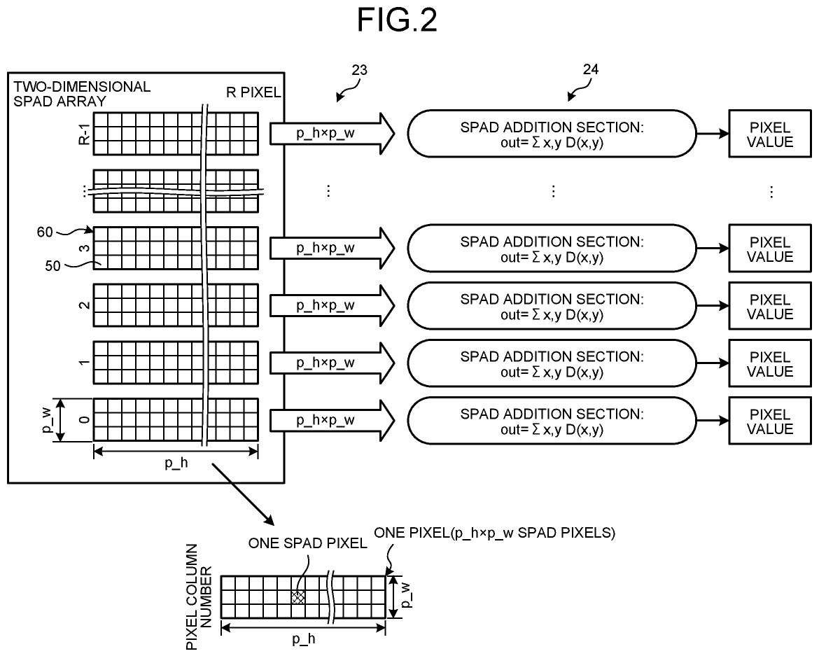

An example of a schematic configuration of a distance measuring device 1 according to a first embodiment will be described with reference to FIGS. 1 and 2. FIG. 1 is a diagram depicting an example of the schematic configuration of the distance measuring device 1 according to the first embodiment. FIG. 2 is a diagram depicting an example of selection processing according to the first embodiment. The present embodiment will describe the distance measuring device 1, referred to as a flash-type device, in which SPAD pixels are arranged in a two-dimensional lattice pattern to acquire a wide-angle distance measurement image at a time.

As depicted in FIG. 1, a distance measuring device 1 according to the first embodiment includes a light source section 10 and a light receiving device 20. The distance measuring device 1 is communicably connected to a host 30. The distance measuring device 1 may include the host 30 in addition to the light source section 10 and the light receiving device 20.

The light source section 10 irradiates a distance measurement target (subject) 40 with light. The light source section 10 includes, for example, a laser beam source that emits pulsed laser beam having a peak wavelength in an infrared wavelength region.

The light receiving device 20 receives reflected light from the distance measurement target 40 based on the irradiation pulsed light from the light source section 10. The light receiving device 20 adopts the ToF method as a measurement method of measuring a distance d to the distance measurement target 40. That is, the light receiving device 20 is a ToF sensor that measures the flight time until the pulsed laser beam emitted from the light source section 10 and reflected by the distance measurement target 40 returns and that obtains the distance d from the time of flight measured.

For example, when the distance measuring device 1 is installed on an automobile or the like, the host 30 may be an engine control unit (ECU) mounted on the automobile or the like. In addition, in a case where the distance measuring device 1 is installed on and used in an autonomous mobile body like an autonomous mobile robot such as a domestic pet robot, a robot vacuum cleaner, an unmanned aerial vehicle, or a tracking conveyance robot, the host 30 may be a device such as control device that controls the autonomous mobile body.

Here, in the distance measurement by the ToF sensor, assuming that the round-trip time until the return of the pulsed laser beam emitted from the light source section 10 toward the distance measurement target 40 and reflected by the distance measurement target 40 to the light receiving device 20 is t [sec], and based on the principle that the light speed C is C≈300,000,000 meters/second, the distance d between the distance measurement target 40 and the light receiving device 20 can be estimated as in the expression d=C×(t/2). For example, when the reflected light is sampled at 1 gigahertz (GHz), one bin (BIN) of the histogram indicates the number of SPAD elements per pixel in which light has been detected in a period of one nanosecond. This corresponds to the distance measurement resolution of 15 centimeters per bin.

(Configuration Example of Light Source Section 10)

For example, the light source section 10 includes one or a plurality of semiconductor laser diodes, and emits a pulsed laser beam L1 having a predetermined time width at a predetermined light emission period (predetermined period). The light source section 10 emits the pulsed laser beam L1 at least toward an angle range equal to or larger than the angle of view of a light receiving surface of the light receiving device 20. Furthermore, the light source section 10 emits the laser beam L1 having a time width of 1 nanosecond at a rate of 1 gigahertz (GHz), for example. For example, in a case where the distance measurement target 40 exists within the distance measuring range, the laser beam L1 emitted from the light source section 10 is reflected by the distance measurement target 40 and will be incident on the light receiving surface of the light receiving device 20 as reflected light L2.

(Configuration Example of Light Receiving Device 20)

The light receiving device 20 includes a control section 21, a light receiving section 22, a selecting section 23, an addition section 24, a histogram processing section 25, a computing section 26, and an external output interface (I/F) 27.

The control section 21 includes an information processing device such as a central processing unit (CPU), for example. The control section 21 controls individual sections in the light receiving device 20.

Although details will be described below, the light receiving section 22 includes, for example, a photon-counting light receiving element that receives light from the distance measurement target 40, for example, a SPAD array section in which pixels including a SPAD element as a light receiving element (hereinafter, referred to as “SPAD pixels”) are two-dimensionally arranged in a matrix (lattice shape). The SPAD element is an example of an avalanche photodiode that operates in a Geiger mode.

For example, after the pulsed laser beam is emitted from the light source section 10, the light receiving section 22 outputs information (for example, information corresponding to the number of detection signals to be described below) related to the number of SPAD elements that has detected incidence of photons (hereinafter, referred to as “detection number”). For example, the light receiving section 22 detects incidence of photons at a predetermined sampling period for a single light emission by the light source section 10, and outputs the photon detection number.

The selecting section 23 groups each SPAD pixel of the SPAD array section into a plurality of pixels each including one or more SPAD pixels. One grouped pixel corresponds to one pixel in a distance measurement image. Therefore, when the number of SPAD pixels (the number of SPAD elements) constituting one pixel and the shape of the region are determined, the number of pixels of the entire light receiving device 20 will be determined, leading to determination of the resolution of the distance measurement image. Note that the selecting section 23 may be incorporated in the light receiving section 22.

For example, as depicted in FIG. 2, the selecting section 23 groups a plurality of SPAD pixels 50 arranged in a two-dimensional array into one pixel 60 for every p_h×p_w pixels. The example of FIG. 2 depicts a two-dimensional SPAD array in which a plurality of SPAD pixels 50 are grouped for every p_h×p_w pixels to form one pixel 60.

Returning to FIG. 1, the addition section 24 adds up (aggregates) the detection number output from the light receiving section 22 for each of the plurality of SPAD elements (for example, corresponding to one or a plurality of pixels), and outputs the added-up value (aggregate value) to the histogram processing section 25 as a pixel value.

For example, as depicted in FIG. 2, the addition section 24 expresses the total of the SPAD values in the pixel 60 as a binary number of ceil(log 2(p_h·p_w)) bits and sets the result as the pixel value of the pixel 60. The SPAD value described above is a value of one SPAD element, and is one-bit data having a value (binary value) of {0, 1}. In addition, the above-described ceil ( ) means a round-up of a decimal number. For example, the addition section 24 is provided in parallel for each pixel 60 as a SPAD addition section. Each addition section 24 simultaneously calculates pixel values of all the pixels 60 and outputs the calculated values to the histogram processing section 25.

Returning to FIG. 1, based on the pixel value obtained for each of one or a plurality of pixels 60, the histogram processing section 25 creates a histogram in which the horizontal axis is the flight time (hereinafter, referred to as “sampling number”) and the vertical axis is an accumulated pixel value. The histogram is created in memory 25a in the histogram processing section 25, for example. The memory 25a can be formed by using a device such as static random access memory (SRAM). However, the memory 25a is not limited to SRAM, and can use various types of memory such as dynamic RAM (DRAM).

The computing section 26 performs computation related to distance measurement. The computing section 26 specifies a flight time when the accumulated pixel value reaches a peak from the histogram created by the histogram processing section 25. Based on the specified flight time, the computing section 26 estimates or calculates, as a distance measurement value, a distance from the light receiving device 20 or a device equipped with the light receiving device to the distance measurement target 40 present within the distance measurement range. The computing section 26 then outputs information of the estimated or calculated distance measurement value to the host 30 or the like via the external output interface 27, for example. The computing section 26 functions as a peak detector.

The external output interface 27 enables communication between the light receiving device 20 and the host 30. The external output interface 27 can be implemented by using an interface such as a mobile industry processor interface (MIPI) and a serial peripheral interface (SPI).

### 1-2. Example of Schematic Configuration of Light Receiving Section 22

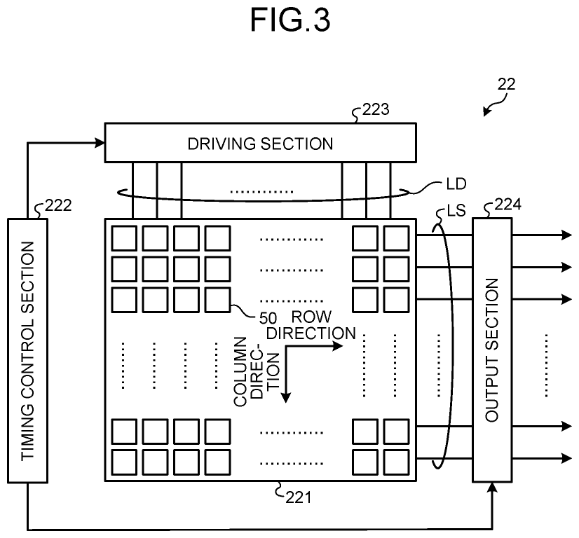

An example of a schematic configuration of the light receiving section 22 according to the first embodiment will be described with reference to FIG. 3. FIG. 3 is a diagram depicting an example of a schematic configuration of the light receiving section 22 according to the first embodiment.

As depicted in FIG. 3, the light receiving section 22 includes a SPAD array section 221, a timing control section 222, a driving section 223, and an output section 224.

The SPAD array section 221 has a configuration including a plurality of SPAD pixels 50 arranged in a two-dimensional matrix. The plurality of SPAD pixels 50 is connected to a pixel drive line LD for each pixel column while being connected to an output signal line LS for each pixel row. One end of the pixel drive line LD is connected to an output end corresponding to each column of the driving section 223, while one end of the output signal line LS is connected to an input end corresponding to each row of the output section 224.

The timing control section 222 includes a timing generator or the like that generates various timing signals. The timing control section 222 controls the driving section 223 and the output section 224 on the basis of various timing signals generated by the timing generator.

The driving section 223 includes a shift register, an address decoder, and the like, and drives each SPAD pixel 50 of the SPAD array section 221 while selecting all the pixels simultaneously or selecting pixels in units of pixel columns, or the like.

Specifically, the driving section 223 includes at least: a circuit that applies a quench voltage V_QCH to be described below to each SPAD pixel 50 in the selected column in the SPAD array section 221; and a circuit that applies a selection control voltage V_SEL to be described below to each SPAD pixel 50 in the selected column. The driving section 223 applies the selection control voltage V_SEL to the pixel drive line LD corresponding to the read target pixel column, thereby selecting, in units of pixel columns, the SPAD pixel 50 to be used for detecting the incidence of photons. A signal V_OUT output from each SPAD pixel 50 of the pixel column selectively scanned by the driving section 223 (hereinafter, referred to as a “detection signal”) is supplied to the output section 224 through each of the output signal lines LS.

The output section 224 outputs, via the selecting section 23, the detection signal V_OUT supplied from each SPAD pixel 50 to the addition section 24 (refer to FIGS. 1 and 2), specifically to each SPAD addition section (refer to FIG. 2) provided for each pixel 60 described above, for example. Note that the selecting section 23 may be incorporated in the output section 224.

### 1-3. Example of Schematic Configuration of SPAD Array Section 221

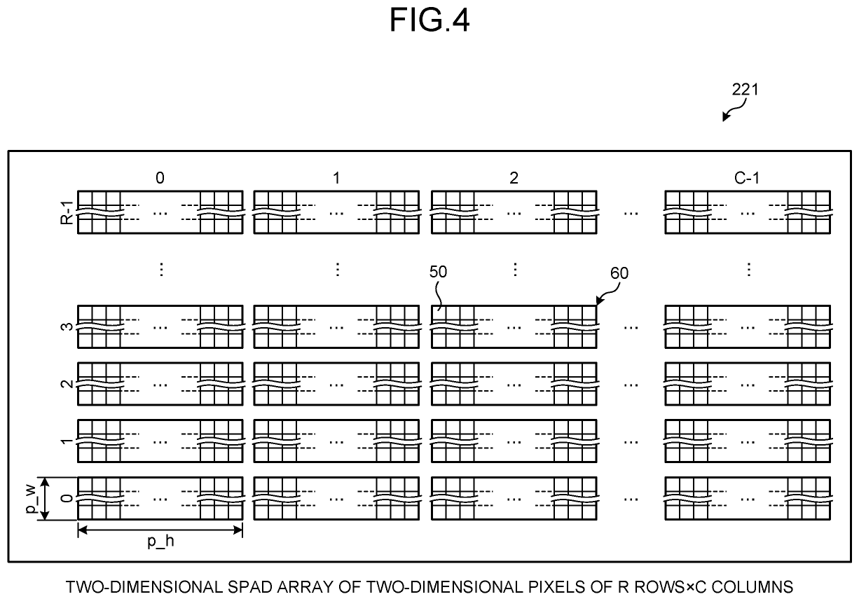

An example of a schematic configuration of the SPAD array section 221 according to the first embodiment will be described with reference to FIG. 4. FIG. 4 is a diagram depicting an example of a schematic configuration of the SPAD array section 221 according to the first embodiment.

As depicted in FIG. 4, the SPAD array section 221 has a configuration in which a plurality of SPAD pixels 50 is two-dimensionally arranged in a matrix, for example. The plurality of SPAD pixels 50 are grouped as each pixel 60 having a predetermined number of SPAD pixels 50 arranged in the row direction and/or the column direction. The shape of the region connecting the outer edges of the SPAD pixels 50 located at an outermost periphery of each pixel 60 is a predetermined shape (for example, a rectangle). Note that the unit of read may be a unit of column or a unit of row, for example, and is appropriately selected according to the configuration of the SPAD array section 221 or the like.

### 1-4. Example of Schematic Configuration of SPAD Pixel 50

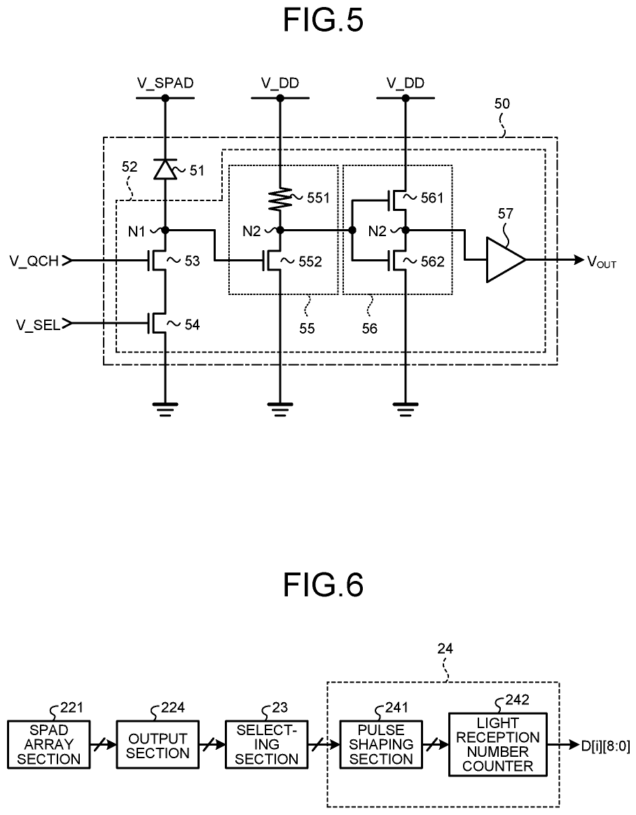

An example of a schematic configuration of the SPAD pixel 50 according to the first embodiment will be described with reference to FIG. 5. FIG. 5 is a diagram depicting an example of a schematic configuration of the SPAD pixel 50 according to the first embodiment.

As depicted in FIG. 5, the SPAD pixel 50 includes: a SPAD element 51 which is an example of a light receiving element; and a read circuit 52.

The SPAD element 51 is an avalanche photodiode that operates in the Geiger mode when a reverse bias voltage V SPAD equal to or higher than a breakdown voltage is applied between the anode electrode and the cathode electrode, and can detect incidence of one photon. That is, the SPAD element 51 generates an avalanche current when photons are incident in a state where a reverse bias voltage equal to or higher than the breakdown voltage is applied between the anode electrode and the cathode electrode.

The read circuit 52 detects incidence of photons on the SPAD element 51. The read circuit 52 includes a quench resistor 53, a selection transistor 54, a digital converter 55, an inverter 56, and a buffer 57.

The quench resistor 53 includes, for example, an N-type Metal Oxide Semiconductor Field Effect Transistor (MOSFET): hereinafter, referred to as an “NMOS transistor”), having its drain electrode connected to an anode electrode of the SPAD element 51 and having its source electrode grounded via the selection transistor 54. Furthermore, the gate electrode of the NMOS transistor constituting the quench resistor 53 is an electrode to which a preset quench voltage V_QCH for allowing the NMOS transistor to act as a quench resistor is applied from the driving section 223 (refer to FIG. 3) via the pixel drive line LD.

The selection transistor 54 is, for example, an NMOS transistor having its drain electrode connected to the source electrode of the NMOS transistor constituting the quench resistor 53, and having its source electrode grounded. When the selection control voltage V_SEL is applied to the gate electrode of the selection transistor 54 from the driving section 223 (refer to FIG. 3) via the pixel drive line LD, the selection transistor 54 changes from the off state to the on state.

The digital converter 55 includes a resistance element 551 and an NMOS transistor 552. The NMOS transistor 552 has its drain electrode connected to a node of a power supply voltage V_DD via the resistance element 551, and having its source electrode grounded. In addition, the gate electrode of the NMOS transistor 552 is connected to a connection node N1 between the anode electrode of the SPAD element 51 and the quench resistor 53.

The inverter 56 has a configuration of a CMOS inverter including a P-type MOSFET (hereinafter, referred to as a “PMOS transistor”) 561 and an NMOS transistor 562. The PMOS transistor 561 has its drain electrode connected to the node of the power supply voltage V_DD, and having its source electrode connected to a drain electrode of the NMOS transistor 562. The NMOS transistor 562 has its drain electrode connected to the source electrode of the PMOS transistor 561, and having its source electrode grounded. The gate electrode of the PMOS transistor 561 and the gate electrode of the NMOS transistor 562 are commonly connected to a connection node N2 with the resistance element 551 and the drain electrode of the NMOS transistor 552. An output end of the inverter 56 is connected to an input end of the buffer 57.

The buffer 57 is a circuit for impedance conversion. When the output signal is input from the inverter 56, the buffer 57 performs impedance conversion on the input output signal and outputs the converted signal as a detection signal V_OUT.

Such a read circuit 52 operates as follows, for example. That is, first, during a period in which the selection control voltage V_SEL is applied from the driving section 223 (refer to FIG. 3) to the gate electrode of the selection transistor 54 and the selection transistor 54 is turned on, the reverse bias voltage V SPAD equal to or higher than the breakdown voltage is applied to the SPAD element 51. This enables operation of the SPAD element 51.

On the other hand, in a period in which the selection control voltage V_SEL is not applied from the driving section 223 to the selection transistor 54 and the selection transistor 54 is in the OFF state, the reverse bias voltage VS PAD is not applied to the SPAD element 51. Accordingly, the operation of the SPAD element 51 is disabled.

When photons are incident on the SPAD element 51 while the selection transistor 54 is turned on, an avalanche current is generated in the SPAD element 51. This allows the avalanche current to flow through the quench resistor 53, increasing the voltage of the connection node N1. When the voltage of the connection node N1 exceeds the on-voltage of the NMOS transistor 552, the NMOS transistor 552 is turned on, changing the voltage of the connection node N2 from the power supply voltage V_DD to 0 V.

When the voltage of the connection node N2 changes from the power supply voltage V_DD to 0 V, the PMOS transistor 561 changes from the off state to the on state, the NMOS transistor 562 changes from the on state to the off state, and the voltage of the connection node N3 changes from 0 V to the power supply voltage V_DD. As a result, the high-level detection signal V_OUT is output from the buffer 57.

Thereafter, when the voltage of the connection node N1 continues to increase, the voltage applied between the anode electrode and the cathode electrode of the SPAD element 51 becomes lower than the breakdown voltage. This stops the avalanche current and lowers the voltage of the connection node N1. When the voltage of the connection node N1 becomes lower than the on-voltage of the NMOS transistor 552, the NMOS transistor 552 is turned off, stopping the output of the detection signal V_OUT from the buffer 57. That is, the detection signal V_OUT turns to a low level.

In this manner, the read circuit 52 outputs the high-level detection signal V_OUT during a period from the timing at which the NMOS transistor 552 is turned on, which has been caused by the incidence of the photon to the SPAD element 51 and resultant generation of the avalanche current, to the timing at which the NMOS transistor 552 is turned off after the avalanche current has stopped.

The detection signal V_OUT output from the read circuit 52 is input from the output section 224 (refer to FIG. 3) to the addition section 24 (refer to FIG. 2), that is, the SPAD addition section for each pixel 60 via the selecting section 23. Therefore, the SPAD addition section for each pixel 60 receives input of the detection signal V_OUT of the number (detection number) of SPAD pixels 50 in which the incidence of photons has been detected, among the plurality of SPAD pixels 50 constituting one pixel 60.

### 1-5. Example of Schematic Configuration of Addition Section 24

An example of a schematic configuration of the addition section 24 according to the first embodiment will be described with reference to FIG. 6. FIG. 6 is a diagram illustrating an example of a schematic configuration of the addition section 24, that is, each SPAD addition section according to the first embodiment.

As depicted in FIG. 6, the addition section 24 includes a pulse shaping section 241 and a light reception number counter 242, for example.

The pulse shaping section 241 shapes a pulse waveform of the detection signal V_OUT detected by the SPAD array section 221 and supplied from the output section 224 via the selecting section 23 into a pulse waveform having a time width according to the operation clock of the addition section 24.

The light reception number counter 242 counts the detection signal V_OUT input from the corresponding pixel 60 for each sampling period, and records the count number (detection number) of the SPAD pixels 50 in which the incidence of photons has been detected for each sampling period, and outputs the recorded count value as a pixel value D of the pixel 60.

In the pixel values D[i][8:0] in the example of FIG. 6, [i] is an identifier that specifies each SPAD pixel 50, which is a value in a range of “0” to “R−1” (refer to FIGS. 2 and 4) in the present embodiment. Furthermore, [8:0] indicates the number of bits of the pixel value D[i]. FIG. 6 depicts a case where the addition section 24 generates a 9-bit pixel value D that can take values in a range of “0” to “511” on the basis of the detection signal V_OUT input from the pixel 60 specified by the identifier i.

Here, the sampling period is a period of performing the measurement of the time (flight time) from emission of the laser beam L1 by the light source section 10 to detection of incidence of photons at the light receiving section 22 of the light receiving device 20 (refer to FIG. 1). The sampling period is set to a period shorter than the light emission period of the light source section 10. For example, by further shortening the sampling period, it is possible to estimate or calculate the flight time of the photon emitted from the light source section 10 and reflected by the distance measurement target 40 with higher time resolution. This means that increasing the sampling frequency makes it possible to estimate or calculate the distance to the distance measurement target 40 with higher distance measurement resolution.

For example, assuming that the flight time from the emission of the laser beam L1 by the light source section 10 to the incidence, on the light receiving section 32, of reflected light L2, which is obtained by reflection of the laser beam L1 on the distance measurement target 40, is t, and based on the principle that the light speed C is constant (C≈300,000,000 meters/second), the distance d to the distance measurement target 40 can be estimated or calculated from the above-described equation (d=C×(t/2)).

When the sampling frequency is 1 gigahertz, the sampling period will be 1 nanosecond. In that case, one sampling period corresponds to 15 centimeters. This indicates that the distance measurement resolution is 15 centimeters when the sampling frequency is 1 gigahertz. In addition, when the sampling frequency is doubled to 2 gigahertz, the sampling period will be 0.5 nanoseconds, and thus one sampling period corresponds to 7.5 centimeters. This indicates that doubling the sampling frequency will be able to halve the distance measurement resolution. In this manner, by increasing the sampling frequency and shortening the sampling period, it is possible to estimate or calculate the distance to the distance measurement target 40 with higher accuracy.

### 1-6. Example of Schematic Configuration of Histogram Processing Section 25

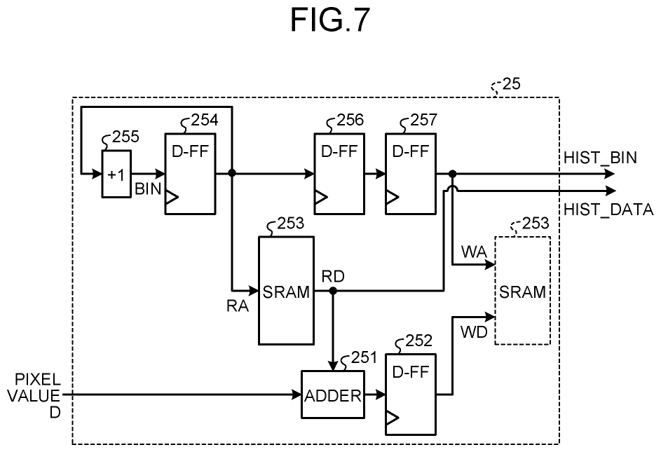

An example of a schematic configuration of the histogram processing section 25 according to the first embodiment will be described with reference to FIG. 7. FIG. 7 is a diagram depicting an example of a schematic configuration of the histogram processing section 25 according to the first embodiment.

The histogram processing section 25 associates the flight time from the emission of the laser beam by the light source section 10 to the return of the reflected light as a bin of the histogram, and stores the pixel value sampled at each time in the memory 25a as a count value of the bin corresponding to the time. The histogram processing section 25 is to add the pixel value at each time of the reflected light from the distance measurement target 40 based on the laser emission performed a plurality of times to the count value of the bin corresponding to the time to update the histogram. Distance measurement computation is performed using a histogram obtained by accumulating count values calculated from pixel values obtained by receiving reflected light based on laser emission performed a plurality of times. Hereinafter, the configuration of the histogram processing section 25 will be specifically described.

As depicted in FIG. 7, the histogram processing section 25 includes an adder 251, a D-flip-flop 252, an SRAM 253, a D-flip-flop 254, an adder (+1) 255, a D-flip-flop 256, and a D-flip-flop 257.

Here, the SRAM 633 to which the read address READ_ADDR (RA) is input and the SRAM 633 to which the write address WRITE_ADDR (WA) is input are the same SRAM (memory). The latter SRAM 633 is enabled during the histogram update period.

The pixel value D is input from the addition section 24 (refer to FIGS. 1 and 2) to the histogram processing section 25. The adder 251 performs addition of read data READ DATA (RD) from the SRAM 253 to the input pixel value D.

The D-flip-flop 252 is enabled during the histogram update period and latches the addition result of the adder 251. The D-flip-flop 252 supplies the latched data to the SRAM 253 to which the write address WA is input as write data WRITE DATA (WD).

The D-flip-flop 252 is enabled during the histogram update period and the transfer period of histogram data HIST_DATA. The D-flip-flop 252 supplies the latched data to the SRAM 253 as a read address READ_ADDR. The adder 255 adds 1 to the latch data of D-flip-flop 252 to increment the bin (BIN).

Read data READ DATA read from the SRAM 253 is output as the histogram data HIST_DATA. The D-flip-flop 256 is enabled during the histogram update period and latches the latch data of the D-flip-flop 254. The D-flip-flop 257 is enabled during the histogram update period and latches the latch data of the D-flip-flop 256. The latch data of the D-flip-flop 257 is output as a histogram bin HIST_BIN.

### 1-7. Example of Histogram Creation Processing

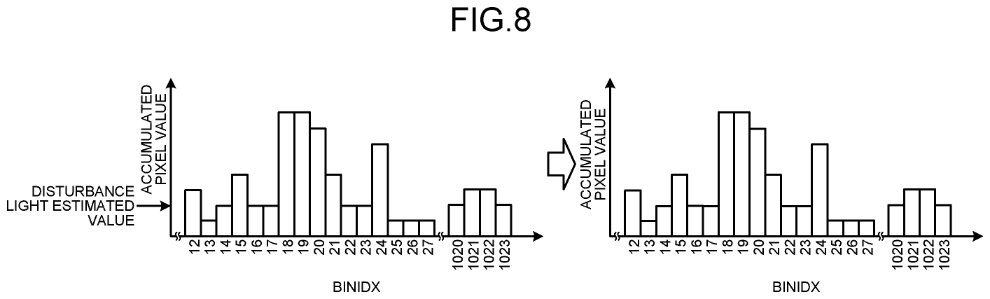

An example of histogram creation processing according to the first embodiment will be described with reference to FIGS. 8 to 10. FIGS. 8 to 10 are diagrams depicting the histogram creation processing according to the first embodiment.

As depicted in FIG. 8, in a case where a histogram as depicted on the left side in FIG. 8 has been obtained for the first light emission of the light source section 10, the histogram to be created in the memory 25a is a histogram as depicted on the right side in FIG. 8 in which a pixel value for each sampling number obtained by sampling for one light emission is stored in the corresponding BIN.

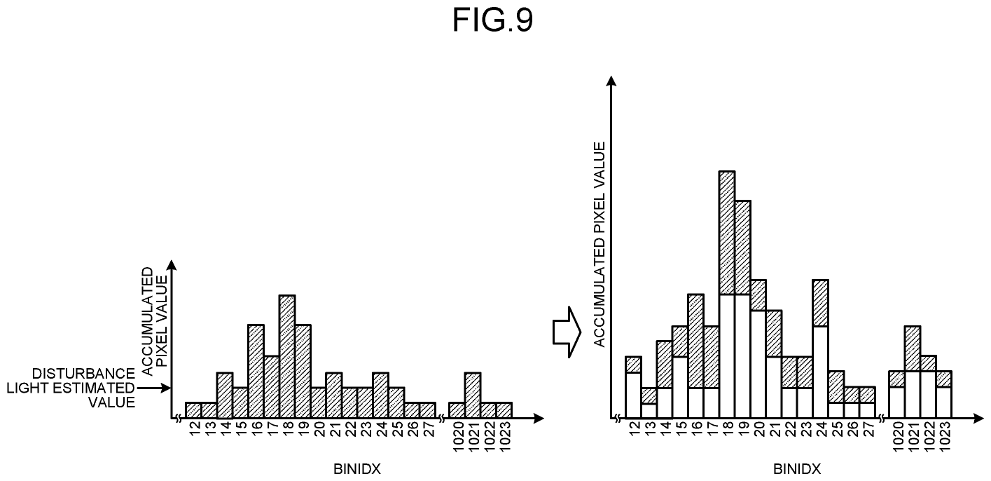

Next, in a case where a histogram as depicted on the left side in FIG. 9 has been obtained for the second light emission of the light source section 10, the histogram to be created in the memory 25a is a histogram as depicted on the right side in FIG. 9 in which the value of each BIN of the histogram obtained for the second light emission has been added to the value of each BIN of the histogram obtained for the first light emission.

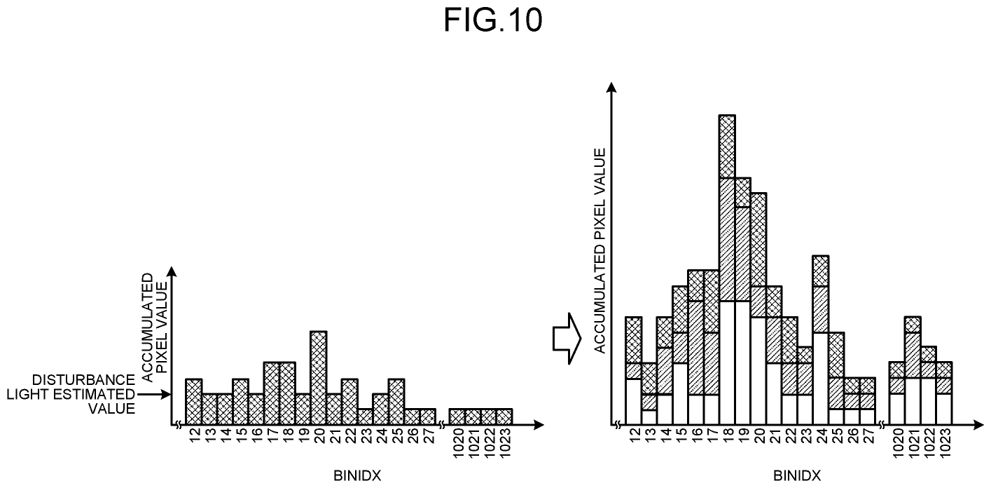

Similarly, in a case where a histogram as depicted on the left side in FIG. 10 has been obtained for the third light emission of the light source section 10, the histogram to be created in the memory 25a is a histogram as depicted on the right side in FIG. 10 in which the value of each BIN of the histogram obtained for the third light emission has been added to the value of each BIN of the histogram obtained for the first light emission and the second light emission.

That is, each BIN in the histogram in the memory 25a stores an accumulated value (accumulated pixel value) of the pixel values obtained in the first light emission to the third light emission. The pixel value of the first reflected light is stored in the memory address of the bin number corresponding to the sampling time (refer to FIG. 8), and the pixel value of the second reflected light is added to the value stored in the memory address of the bin number corresponding to the sampling time (refer to FIG. 9). Furthermore, the pixel value of the third reflected light is added to the value stored in the memory address of the bin number corresponding to the sampling time (refer to FIG. 10).

In this manner, by accumulating the pixel values obtained for the plurality of times of light emission by the light source section 10, it is possible to increase the difference between the accumulated pixel value of the pixel value in which the reflected light L2 has been detected and the accumulated pixel value caused by noise such as disturbance light L0. This can improve the reliability of discrimination between the reflected light L2 and noise, making it possible to estimate or calculate the distance to the distance measurement target 40 with higher accuracy.

Note that, as described above, the light incident on the light receiving section 22 is not only include the reflected light L2 reflected by the distance measurement target 40 and returned but also include the disturbance light L0 reflected and scattered by an object, the atmosphere, or the like. Therefore, the light receiving device 20 may include a disturbance light estimation processing section (not illustrated). Based on the addition result of the addition section 24, the disturbance light estimation processing section estimates the disturbance light L0 incident on the light receiving section 22 together with the reflected light L2 on the basis of an arithmetic average, and gives a disturbance light intensity estimated value to the histogram processing section 25. The histogram processing section 25 performs processing of subtracting the disturbance light intensity estimated value provided from the ambient light estimation processing section and adding the subtracted value to the histogram. For example, when the pixel value of the reflected light is stored in the memory address of the bin number corresponding to the sampling time, the value obtained by subtracting the disturbance light intensity estimated value from the pixel value will be stored in the memory address.

In addition, a smoothing filter may be provided in the light receiving device 20. The smoothing filter is formed with a filter such as a Finite Impulse Response (FIR) filter. This smoothing filter performs smoothing processing so as to easily detect a peak of reflected light by reducing shot noise and reducing the number of unnecessary peaks on the histogram.

### 1-8. Example of Schematic Configuration of Computing Section 26

An example of a schematic configuration of the computing section 26 according to the first embodiment will be described below.

The computing section 26 calculates the distance to the distance measurement target 40 (or the estimated value of the distance) based on the histogram in the memory 25a created by the histogram processing section 25. For example, the computing section 26 specifies a bin number (BIN number) at which the accumulated pixel value reaches a peak value in each histogram, and converts the specified bin number into the flight time (or the distance information), thereby calculating the distance to the distance measurement target 40 (or the estimated value of the distance).

For example, the computing section 26 detects peaks of bell curves by repeating magnitude comparison of count values of adjacent sampling numbers (for example, bin numbers) of the histogram, obtains sampling numbers of rising edges of a plurality of bell curves having large peak values as candidates, and calculates the distance to the distance measurement target 40 based on the flight time of the reflected light. At this time, there may be a case where a plurality of bell curves has been detected. Since the host 30 calculates a final distance measurement value with reference to the information regarding neighboring pixels, information of the distance measurement values of the plurality of reflected light candidates is to be transmitted to the host 30 via the external output interface 27.

Note that the conversion from the bin number to the flight time or the distance information may be executed using a conversion table stored in advance in the predetermined memory 25a, or a conversion formula for converting the bin number into the flight time or the distance information may be held in advance and the conversion may be performed using this conversion formula.

Furthermore, the bin number at which the accumulated pixel value peaks can be specified by using various methods such as a method of specifying the bin number of the bin having the largest value and a method of specifying the bin number at which the accumulated pixel value peaks based on a function curve obtained by performing fitting of the histogram.

### 1-9. Implementation Examples of Selective Addition Processing

### 1-9-1. First Implementation Example

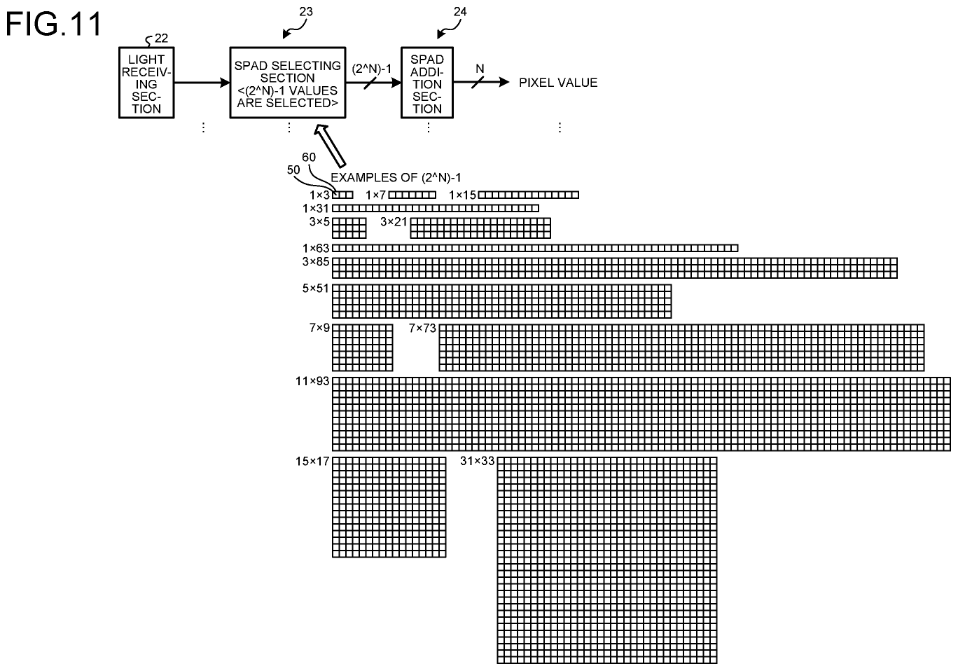

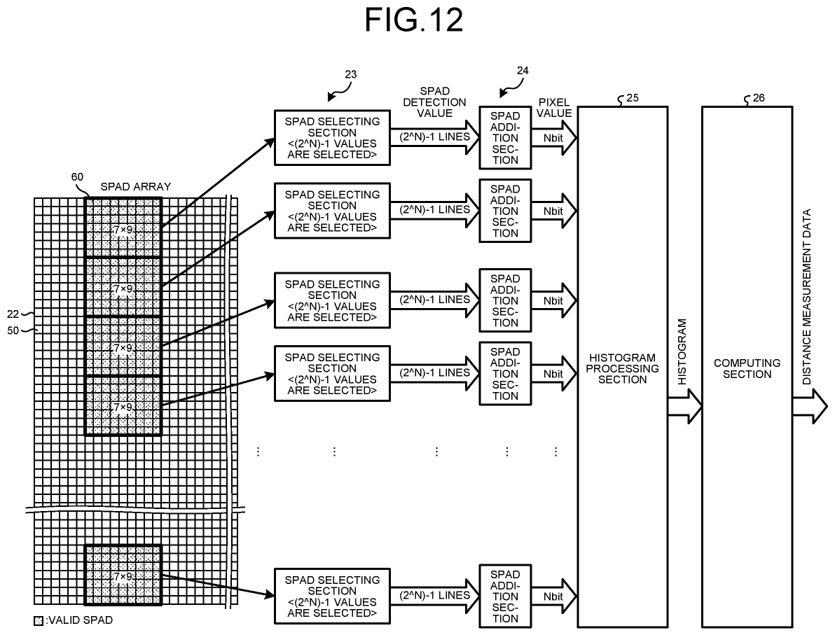

A first implementation example of the selective addition processing according to the first embodiment will be described with reference to FIGS. 11 and 12. FIG. 11 is a diagram depicting a plurality of examples of a rectangular region having 2^{N}−1((2\hat{ }N)−1) SPAD pixels 50 according to the first embodiment. FIG. 12 is a diagram depicting the first implementation example of the selective addition processing according to the first embodiment.

As depicted in FIG. 11, there are at least 14 column×row pattern combinations in which the number of SPAD pixels 50 in a rectangular region is 2^{N}−1 within a 127×127 column×row pattern of the SPAD pixels 50. In the example of FIG. 11, it is possible to use, as one pixel 60, a rectangular region in which the number of SPAD pixels 50 in the column×row pattern is any one of 1×3, 1×7, 1×15, 1×31, 3×5, 3×21, 1×63, 3×85, 5×51, 7×9, 7×73, 11×93, 15×17, and 31×33. Note that N is a positive integer (natural number).

As depicted in FIG. 12, the selecting section 23 selects, a rectangular region having 7×9 SPAD pixels 50 as the pixels 60, for example. The selecting section 23 sets, as the pixel 60, a rectangular region at a position covering a region necessary for the light receiving section 22 to capture the reflected light, being a rectangular region in which the number of valid SPAD pixels 50 included in the region is 2^{N}−1. With this operation, one pixel is represented by N bits. For example, the selecting section 23 is provided in parallel for each pixel 60 as a SPAD selecting section. Each selecting section 23 outputs an individual SPAD detection value of each pixel 60 to each addition section 24.

In the example of FIG. 12, one pixel 60 is constituted with 63 (=2⁶⁻¹) SPAD pixels 50 included in a rectangular region having a column×row pattern of 7×9. In this case, the range includes 64 values of 0 to 63, and one pixel 60 is expressed by 6(=log 2(63+1)) bits. That is, the range that can be expressed by 6 bits includes 2⁶=64 values, and the range of all 64 values is used. This eliminates the waste of computing elements and wiring lines (for example, a computing element that performs computation using a pixel value, a wiring line for transmitting a pixel value, and the like) related to pixel values.

In contrast, for example, in a case where one pixel 60 includes 64 (=2⁶) SPAD pixels 50 included in a rectangular region of a column×row pattern of 8×8, the range has 65 values 0 to 64, and one pixel 60 would be expressed by 7(=log 2(64+1)) bits. That is, the range that can be expressed by 7 bits has 2⁷=124 values, but only the range of 65 values of 0 to 64 would actually be used. This would cause the waste of computing elements and wiring lines related to pixel values.

In this manner, in the first implementation example, by setting a rectangular region in which the number of valid SPAD pixels 50 is 2^{N}−1 as one pixel 60, one pixel is represented by N bits. With this configuration, as compared with a case where a rectangular region in which the number of valid SPAD pixels 50 is 2^{N} is set as one pixel 60, it is possible to suppress waste of computing elements and wiring lines related to pixel values, leading to achievement of circuit scale reduction and power reduction.

### 1-9-2. Second Implementation Example

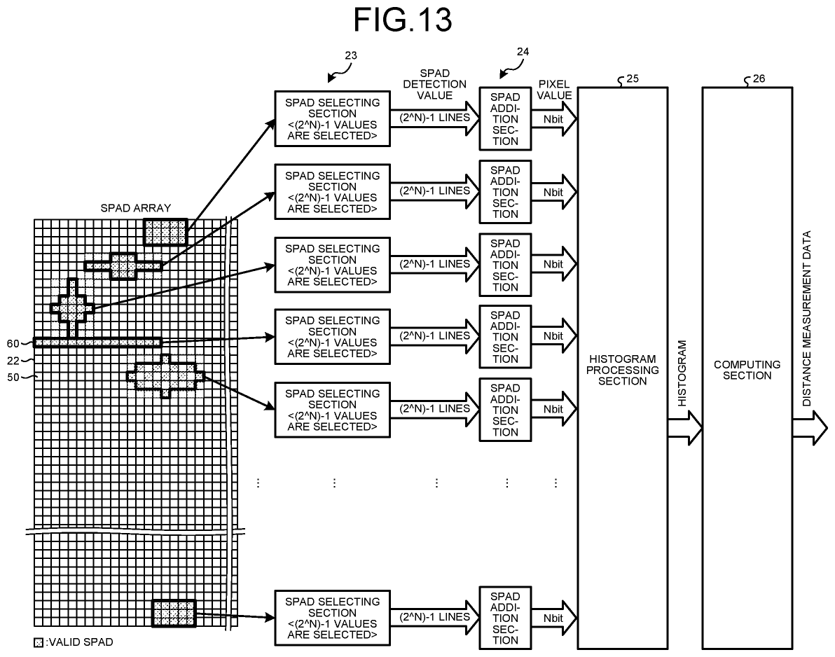

A second implementation example of the selective addition processing according to the first embodiment will be described with reference to FIG. 13. FIG. 13 is a diagram depicting the second implementation example of the selective addition processing according to the first embodiment.

As depicted in FIG. 13, the selecting section 23 selects, as the pixel 60, a free region other than a rectangular region, in which the number of valid SPAD pixels 50 is 2^{N}−1. There are few combinations of 2^{N}−1 among the patterns as rectangular regions. Therefore, the selecting section 23 selects 2^{N}−1 SPAD pixels 50 from the plurality of effective SPAD pixels 50 at positions covering the region necessary for the light receiving section 22 to capture the reflected light, and sets the selected SPAD pixels as the pixel 60. At this time, the region in which the number of valid SPAD pixels 50 is 2^{N}−1 may be other than a rectangular region, and the shape of the region is not limited.

In the example of FIG. 13, one pixel 60 is constituted with 15 (=2⁴−1) SPAD pixels 50. In this case, one pixel is represented by four bits. The SPAD pixels 50 may be continuously and densely selected as in the pattern of the pixels 60 depicted as the first to fourth patterns from the top in FIG. 13. On the other hand, the SPAD pixels 50 do not have to be selected consecutively or densely, and may be selected intermittently with no continuity, as in a pattern of the pixels 60 depicted as a fifth pattern from the top in FIG. 13. By selecting the SPAD pixels 50 with no continuity, a wide range can be covered.

In the example of FIG. 13, the pixels 60 have different patterns (for example, the shape of the pixel 60, the method of selecting the SPAD pixel 50, or the like) for each pixel 60. However, the pattern of each pixel 60 may be unified to a specific pattern (the same pattern), and 2^{N}−1 SPAD pixels 50 may be selected. In addition, it is also possible to use several, specifically, two or three kinds of specific patterns.

In this manner, in the second implementation example, by setting a free region in which the number of valid SPAD pixels 50 is 2^{N}−1 as one pixel 60, one pixel is represented by N bits. With this configuration, as compared with a case where a rectangular region in which the number of valid SPAD pixels 50 is 2^{N} is set as one pixel 60, it is possible to suppress waste of computing elements and wiring lines related to pixel values, leading to achievement of circuit scale reduction and power reduction. Furthermore, since a free region other than the rectangular region can be set as one pixel 60, the degree of freedom in design can be improved.

### 1-9-3. Third Implementation Example

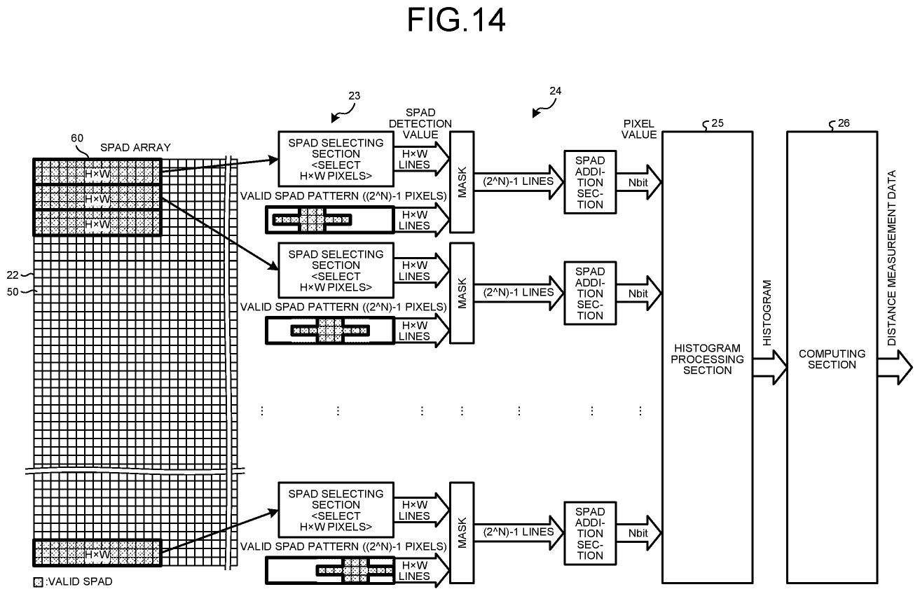

A third implementation example of the selective addition processing according to the first embodiment will be described with reference to FIG. 14. FIG. 14 is a diagram depicting the third implementation example of the selective addition processing according to the first embodiment.

As depicted in FIG. 14, the selecting section 23 selects a rectangular region (H×W) in which the number of valid SPAD pixels 50 is 2^{M}−1 or more, and sets a region in which the number of SPAD pixels 50 included in the selected rectangular region (H×W) is 2^{N}−1 as the pixel 60. At this time, the selected rectangular region (H×W) is processed by a mask having a pattern that validates individual detection values of the 2^{N}−1 SPAD pixels 50. M is a positive integer (natural number) and is larger than N (M>N).

For example, the selecting section 23 selects a rectangular region (H×W) in which the number of valid SPAD pixels 50 is 2^{M}−1 or more, and obtains a total of logical products of the SPAD detection value array and each element of the mask array using an H×W SPAD detection value array of detection values (SPAD detection values) of the SPAD pixels 50 in the selected rectangular region and using an H×W mask array (mask) of a mask pattern in which 2^{N}−1 SPAD pixels 50 are 1, thereby obtaining an N-bit pixel value with a range of 0 to 2^{N}−1. The mask is prepared in advance. This mask is a mask in which values indicating validity or invalidity (for example, 1 indicates validity and 0 indicates invalidity) are arranged in a matrix in a region of the H×W SPAD detection value array. The number of values indicating the validity of the mask is 2^{N}−1.

In this manner, in the third implementation example, by using the above-described mask and setting a region where the number of valid SPAD pixels 50 is 2^{N}−1 as one pixel 60, one pixel 60 is represented by N bits. With this configuration, as compared with a case where a rectangular region in which the number of valid SPAD pixels 50 is 2^{N} is set as one pixel 60, it is possible to suppress waste of computing elements and wiring lines related to pixel values, leading to achievement of circuit scale reduction and power reduction. Furthermore, since the H×W rectangular region to be selected first does not need to be a region in which the number of valid SPAD pixels 50 is 2^{N}−1, it is possible to improve the degree of freedom in design.

### 1-9-4. Fourth Implementation Example

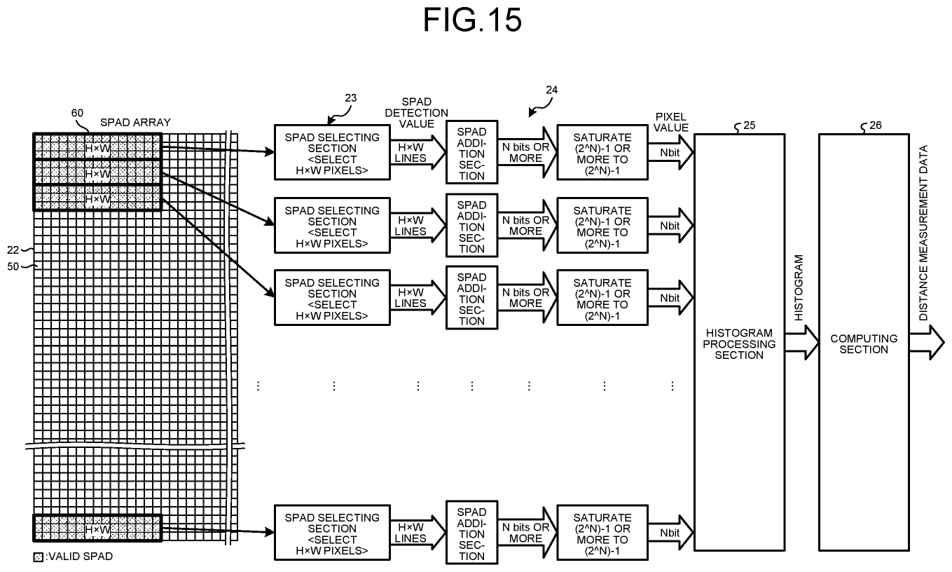

A fourth implementation example of the selective addition processing according to the first embodiment will be described with reference to FIG. 15. FIG. 15 is a diagram depicting the fourth implementation example of the selective addition processing according to the first embodiment.

As depicted in FIG. 15, the selecting section 23 selects a rectangular region (H×W) in which the number of valid SPAD pixels 50 is 2^{M}−1 or more. The addition section 24 calculates the total of the elements (binary values) in the SPAD detection value array of 2^{M}−1 or more. In a case where the calculated value is 2^{N}−1 or more, the calculated value is saturated to 2^{N}−1 and used. In a case where the calculated value is smaller than 2^{N}−1, the calculated value is used to obtain an N-bit pixel value having a range of 0 to 2^{N}−1.

In this manner, in fourth implementation example, the total of the elements (binary values) in the SPAD detection value array of 2^{N}−1 or more is calculated, and the calculated value of 2^{N}−1 or more is saturated to 2^{N}−1, whereby one pixel is expressed by N bits. With this configuration, as compared with a case where a rectangular region in which the number of valid SPAD pixels 50 is 2^{N} is set as one pixel 60, it is possible to suppress waste of computing elements and wiring lines related to pixel values, leading to achievement of circuit scale reduction and power reduction. Furthermore, since the H×W rectangular region to be selected first does not need to be a region in which the number of valid SPAD pixels 50 is 2^{N}−1, it is possible to improve the degree of freedom in design.

### 1-9-5. Fifth Implementation Example

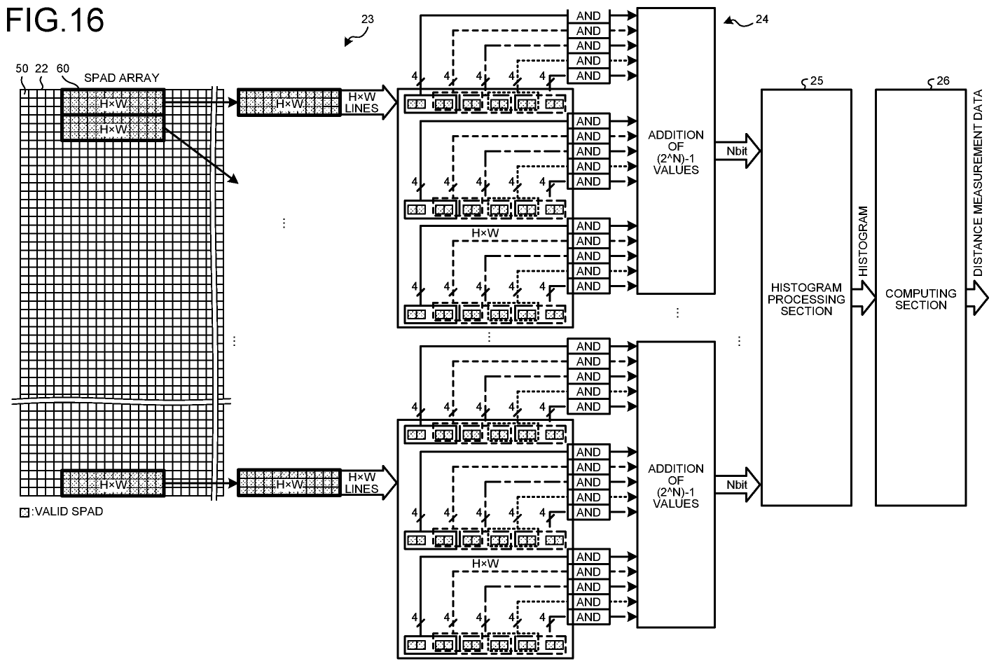

A fifth implementation example of the selective addition processing according to the first embodiment will be described with reference to FIG. 16. FIG. 16 is a diagram depicting the fifth implementation example of the selective addition processing according to the first embodiment.

As depicted in FIG. 16, the selecting section 23 selects a rectangular region (H×W) in which the number of valid SPAD pixels 50 is 2^{M}−1 or more. The addition section 24 has 2^{N}−1 lines of output (for example, an output line) that indicate 1 when a predetermined number (four in the example of FIG. 16) of SPAD pixels 50 simultaneously indicate 1, and sets the total of the outputs of the 2^{N}−1 lines as a pixel value. For example, using AND operation, the addition section 24 outputs 1 only when the plurality of SPAD pixels 50 simultaneously indicates 1, and outputs 0 at other times. Note that the pixel region of a predetermined number of SPAD pixels 50 may overlap with another pixel region of a predetermined number of SPAD pixels 50. The overlapping pixel regions may overlap with each other not only in the horizontal direction but also in the vertical direction or the diagonal direction.

Here, in order to reduce the influence of disturbance light that is temporally and spatially incoherent by utilizing the fact that the laser emitted from the light source section 10 is coherent light (having coherence), there is a method of determining that light is detected when the adjacent SPAD pixels 50 simultaneously have detected light as described above. In this case, the number of lines of output that indicate 1 when the predetermined number of SPAD pixels 50 simultaneously indicated 1 is set to 2^{N}−1.

In this manner, in the fifth implementation example, with a configuration of the rectangular region (H×W), in which the number of lines of output that indicate 1 when a predetermined number (four in the example of FIG. 16) of SPAD elements 51 at a predetermined time simultaneously have received light is set to 2^{N}−1, generation of 2^{N}−1 binary values are performed, and all the 2^{N}−1 binary values are added up, whereby one pixel is represented by N bits. With this configuration, as compared with a case where a rectangular region in which the number of valid SPAD pixels 50 is 2^{N} is set as one pixel 60, it is possible to suppress waste of computing elements and wiring lines related to pixel values, leading to achievement of circuit scale reduction and power reduction. Furthermore, since the H×W rectangular region to be selected first does not need to be a region in which the number of valid SPAD pixels 50 is 2^{N}−1, it is possible to improve the degree of freedom in design.

### 1-9-6. Sixth Implementation Example

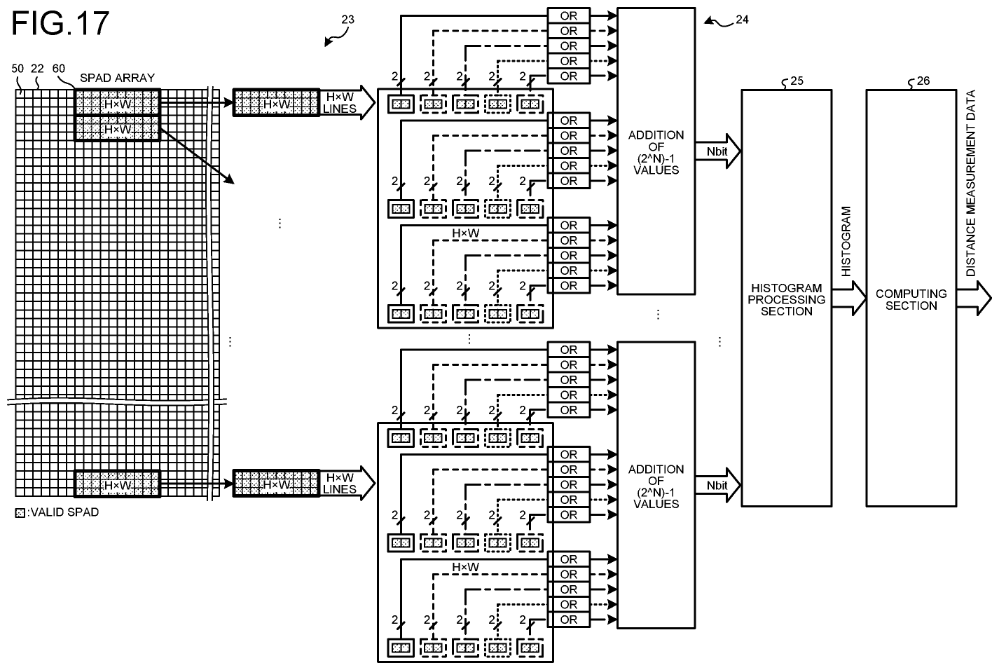

A sixth implementation example of the selective addition processing according to the first embodiment will be described with reference to FIG. 17. FIG. 17 is a diagram depicting the sixth implementation example of the selective addition processing according to the first embodiment.

As depicted in FIG. 17, the selecting section 23 selects a rectangular region (H×W) in which the number of valid SPAD pixels 50 is 2^{M}−1 or more. The addition section 24 has 2^{N}−1 lines of output (for example, an output line) that indicate 1 when one or more of a predetermined number (two in the example of FIG. 17) of SPAD pixels 50 indicate 1, and sets the total of the outputs of the 2^{N}−1 lines as a pixel value. For example, using OR operation, the addition section 24 outputs 1 when one or more of the plurality of SPAD pixels 50 indicate 1, and outputs 0 when all the SPAD pixels indicate 0. Note that applying OR operation on each output value corresponds to performing saturation for reducing the range before addition. The pixel region of the predetermined number of SPAD pixels 50 is set not to overlap with another pixel region of the predetermined number of SPAD pixels 50.

In this manner, in the sixth implementation example, with a configuration of the rectangular region (H×W), in which the number of lines of output that indicate 1 when one or more of a predetermined number (two in the example of FIG. 17) of SPAD elements 51 at a predetermined time have received light is set to 2^{N}−1, generation of 2^{N}−1 binary values are performed, and all the 2^{N}−1 binary values are added up, whereby one pixel is represented by N bits. With this configuration, as compared with a case where a rectangular region in which the number of valid SPAD pixels 50 is 2^{N} is set as one pixel 60, it is possible to suppress waste of computing elements and wiring lines related to pixel values, leading to achievement of circuit scale reduction and power reduction. Furthermore, since the H×W rectangular region to be selected first does not need to be a region in which the number of valid SPAD pixels 50 is 2^{N}−1, it is possible to improve the degree of freedom in design.

### 1-9-7. Seventh Implementation Example

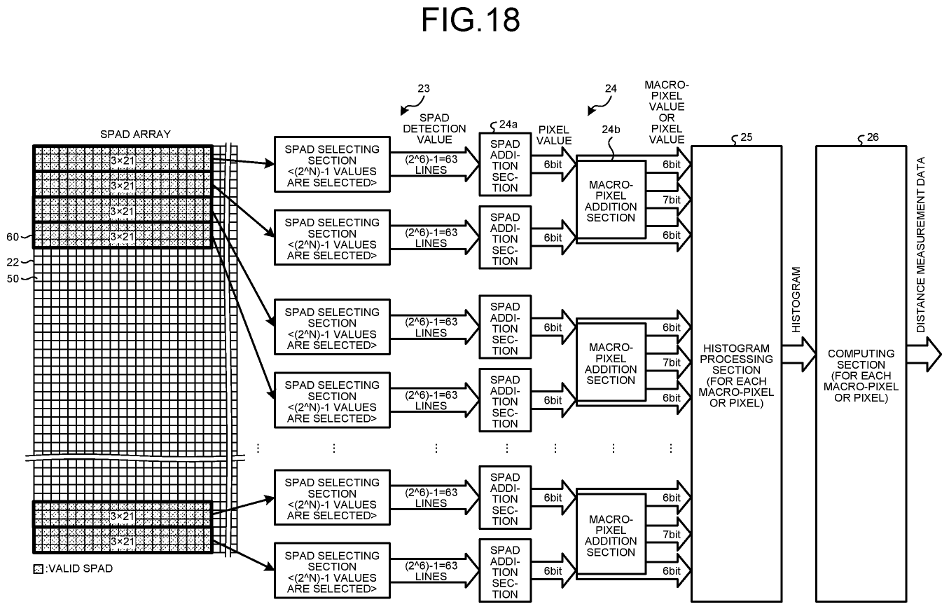

A seventh implementation example of the selective addition processing according to the first embodiment will be described with reference to FIG. 18. FIG. 18 is a diagram depicting the seventh implementation example of the selective addition processing according to the first embodiment.

As depicted in FIG. 18, the selecting section 23 selects a rectangular region (H×W: 3×21 in the example of FIG. 18) in which the number of valid SPAD pixels 50 is 2^{M}−1. The addition section 24 is configured to enable distance measurement by switching between a pixel value with a fine resolution but a small range and a macro-pixel value with a coarse resolution but a large range. The macro-pixel value is a value obtained by summing the pixel values of the pixel 60 constituted with 2^{N}−1 SPAD pixels 50 after calculating a power of 2.

For example, the addition section 24 includes: a SPAD addition section 24a provided in parallel for each of the pixels 60; and a macro-pixel addition section 24b provided in parallel for each of the two SPAD addition sections 24a. In the example of FIG. 18, the SPAD addition section 24a outputs a pixel value with 6 bits to the histogram processing section 25 or the macro-pixel addition section 24b. The macro-pixel addition section 24b outputs the pixel value with 7 bits to the histogram processing section 25. The SPAD addition section 24a corresponds to a first addition section, and the macro-pixel addition section 24b corresponds to a second addition section.

In the example of FIG. 18, in a 3×21 pixel region in which the number of valid SPAD pixels 50 is 63, the pixel value has a range of 0 to 63 values, and the pixel value has a bit width of 6 bits. In addition, the macro-pixel value has a range of 0 to 126 values, and the pixel value has a bit width of 7 bits (the maximum value that can be expressed by 7 bits is 127). In this manner, in the seventh implementation example, when the 2^{N}−1 SPAD pixels 50 are set as minimum unit pixels, the number of bits of a macro-pixel in which the minimum unit pixels are grouped by a plurality of, that is, 2^{N} SPAD pixels is also close to the maximum value that can be expressed by the number of bits, and thus, there is less waste. This is effective with an elongated minimum pixel such as a 1×31 pattern. This makes it possible to suppress waste of computing elements and wiring lines related to pixel values, leading to achievement of circuit scale reduction and power reduction. Incidentally, similar to the fourth implementation example, it is also possible to perform a modification in which the pixel value is saturated to 2^{N}−1 after the macro-pixel addition.

### 1-10. Action and Effects

As described above, according to the first embodiment, there are provided: the light receiving section 22 including a plurality of the SPAD elements 51 (an example of a photon-counting light receiving element) that receives reflected light from the distance measurement target 40 based on irradiation pulsed light from the light source section 10; the selecting section 23 that selects individual detection values of the plurality of SPAD elements 51 at a predetermined time; the addition section 24 that generates 2^{N}−1 binary values (N is a positive integer) from the individual detection values of the plurality of SPAD elements 51 at the predetermined time selected by the selecting section 23 and calculates an N-bit pixel value by adding up all the 2^{N}−1 binary values; and the computing section 26 that performs computation related to distance measurement using the N-bit pixel value calculated by the addition section 24 (refer to the first to seventh implementation examples). For example, in a case where one pixel 60 includes 63 (=2⁶⁻¹) SPAD pixels 50 (SPAD elements 51) included in a rectangular region of a column×row pattern of 7×9, the number of SPAD pixels is 64 with a range of 0 to 63 values, and one pixel 60 is expressed by 6(=log 2(63+1)) bits. That is, the range that can be expressed by 6 bits will include 2 6=64 values, and the range of all 64 values will be used. Therefore, as compared with a case where computing elements and wiring lines related to pixel values are installed corresponding to an extra range, it is possible to reduce the waste of computing elements and wiring lines related to pixel values (such as the computing element that performs computation using a pixel value or a wiring line for transmitting the pixel value). In this manner, it is possible to suppress waste of computing elements and wiring lines related to pixel values, leading to achievement of circuit scale reduction and power reduction.

Furthermore, the selecting section 23 may select individual detection values of the 2^{N}−1 SPAD elements 51 at a predetermined time (refer to the first and second implementation examples). This makes it possible for the addition section 24 to easily generate 2^{N}−1 binary values from the individual detection values of the plurality of SPAD elements 51 at the predetermined time selected by the selecting section 23 and add up all the 2^{N}−1 binary values to calculate an N-bit pixel value, leading to achievement of higher processing speed as compared with complicated processing.

Furthermore, the selecting section 23 may select each detection value of the 2^{N}−1 SPAD elements 51 at a predetermined time from a rectangular region in which the number of SPAD elements 51 is 2^{N}−1 in the light receiving section 22 (refer to the first implementation example). This makes it possible for the selecting section 23 to easily select the individual detection values of the 2^{N}−1 SPAD elements 51 at the predetermined time, leading to achievement of higher processing speed as compared with complicated processing.

Furthermore, the selecting section 23 may select individual detection values of the 2^{N}−1 SPAD elements 51 at a predetermined time from a rectangular region in which the number of SPAD elements 51 is 2^{M}−1 or more (M is a positive integer larger than N) in the light receiving section 22 (refer to the third implementation example). This makes it possible to do without using a rectangular region in which the number of SPAD elements 51 is 2^{N}−1 as the above-described rectangular region, improving the degree of freedom in design.

Furthermore, the selecting section 23 may select the individual detection values of the 2^{N}−1 SPAD elements 51 at the predetermined time from a rectangular region in which the number of SPAD elements 51 is 2^{M}−1 or more in the light receiving section 22 by using a mask that validates the individual detection values of the 2^{N}−1 SPAD elements 51 at the predetermined time (refer to the third implementation example). This makes it easier, using the mask, to select individual detection values of 2^{N}−1 SPAD elements 51 at a predetermined time from the rectangular region in which the number of SPAD elements 51 is 2^{M}−1 or more in the light receiving section 22, leading to achievement of higher processing speed as compared with complicated processing.

Furthermore, the selecting section 23 may select individual detection values of the 2^{M}−1 or more SPAD elements 51 at a predetermined time, and the addition section 24 may add up the individual binary values of the 2^{N}−1 or more SPAD elements 51 selected by the selecting section 23 and calculate an N-bit pixel value by setting the added-up value that is 2^{N}−1 or more to 2^{N}−1 (refer to the fourth implementation example). This makes it possible to calculate N-bit pixel values even when individual detection values of the 2^{M}−1 or more SPAD elements 51 at a predetermined time are selected, leading to improvement of the degree of freedom in design.

Furthermore, the addition section 24 may generate 2^{N}−1 binary values by setting the number of lines of output that indicates 1 when a predetermined number of SPAD elements 51 at a predetermined time have simultaneously received light to 2^{N}−1, and may calculate an N-bit pixel value by adding up all the 2^{N}−1 binary values (refer to the fifth implementation example). This makes it possible to calculate the N-bit pixel value even in a case where light is determined to be detected when the adjacent SPAD pixels 50 has simultaneously detected light, leading to improvement of the degree of freedom in design.

Furthermore, the addition section 24 may generate 2^{N}−1 binary values by setting the number of lines of output that indicates 1 when one or more of a predetermined number of SPAD elements 51 at a predetermined time has received light to 2^{N}−1, and may calculate an N-bit pixel value by adding all the 2^{N}−1 binary values (refer to the sixth implementation example). This makes it possible to calculate the N-bit pixel value even in a case where light is determined to be detected when one or more of the adjacent SPAD pixels 50 has detected light, leading to improvement of the degree of freedom in design.

Furthermore, the addition section 24 may include: the SPAD addition section (an example of the first addition section) 24a that calculates an N-bit pixel value by adding up all the 2^{N}−1 binary values; and the macro-pixel addition section (an example of the second addition section) 24b that calculates a macro-pixel value by adding up a plurality of N-bit pixel values calculated by the SPAD addition section 24a, and the computing section 26 may perform computation related to distance measurement using the macro-pixel value calculated by the macro-pixel addition section 24b (refer to the seventh implementation example). This makes it possible to achieve circuit scale reduction and power reduction using the macro-pixel value as well.

Furthermore, there is provided the memory 25a that stores the N-bit pixel value or the histogram of the macro-pixels calculated by the addition section 24, and the computing section 26 may perform computation related to distance measurement using the histogram stored in the memory 25a. This makes it possible to perform computation related to distance measurement using the histogram stored in the memory 25a, leading to achievement of higher processing speed as compared with complicated processing.

### 2. Second Embodiment

### 2-1. Schematic Configuration Example of Distance Measuring Device

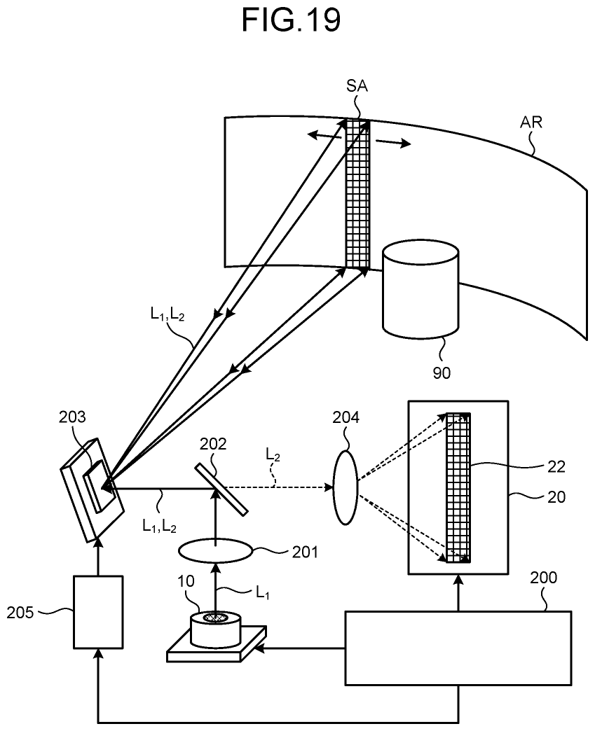

An example of a schematic configuration of a distance measuring device according to a second embodiment will be described with reference to FIG. 19. FIG. 19 is a diagram depicting an example of the schematic configuration of the distance measuring device according to the second embodiment. In the first embodiment, a distance measuring device referred to as a flash-type device has been described as an example. In contrast, in the second embodiment, a distance measuring device referred to as a scan-type device will be described as an example. In the following description, the components similar to those of the first embodiment are denoted by the same reference numerals, and redundant description thereof will be omitted.

As depicted in FIG. 19, the distance measuring device according to the second embodiment includes, in addition to the light source section 10 and the light receiving device 20 according to the first embodiment: a control device 200; a condenser lens 201; a half mirror 202; a micromirror 203; a light receiving lens 204; and a scanning section 205.

The control device 200 includes an information processing device such as a central processing unit (CPU), for example. The control device 200 controls the light source section 10, the light receiving device 20, the scanning section 205, and the like.

The condenser lens 201 condenses a laser beam L1 emitted from the light source section 10. For example, the condenser lens 201 condenses the laser beam L1 so as to allow the laser beam L1 to expand to an area equivalent to the angle of view of the light receiving surface of the light receiving device 20.

The half mirror 202 reflects at least a part of the incident laser beam L1 toward the micromirror 203. Note that, instead of the half mirror 202, it is also possible to use an optical element such as a polarization mirror that reflects a part of light and transmits another part of light.

The micromirror 203 is attached to the scanning section 205 so that the angle can be changed about the center of a reflecting surface. For example, the scanning section 205 causes the micromirror 203 to swing or vibrate in the horizontal direction such that an image SA of the laser beam L1 reflected by the micromirror 203 horizontally reciprocates in a predetermined scan area AR. For example, the scanning section 205 causes the micromirror 203 to swing or vibrate in the horizontal direction such that the image SA of the laser beam L1 reciprocates in the predetermined scan area AR in 1 milliseconds (ms). The swinging or vibrating operation of the micromirror 203 can be implemented by using a device such as a stepping motor and a piezo element.

Here, the micromirror 203 and the scanning section 205 constitute a scanning part that scans light incident on the light receiving section 22 of the light receiving device 20. Note that the scanning part may include at least one of the condenser lens 201, the half mirror 202, and the light receiving lens 204 in addition to the micromirror 203 and the scanning section 205.

In the distance measuring device having such a configuration, reflected light L2 of the laser beam L1 reflected by an object 90 (an example of the distance measurement target 40) existing in the distance measuring range is incident on the micromirror 203 from the direction opposite to the laser beam L1 with an incident axis, which is the same optical axis as an emission axis of the laser beam L1. The reflected light L2 incident on the micromirror 203 is then incident on the half mirror 202 along the same optical axis as the laser beam L1, and a part of the reflected light L2 is transmitted through the half mirror 202. The image of the reflected light L2 transmitted through the half mirror 202 is formed on a pixel column in the light receiving section 22 of the light receiving device 20 through the light receiving lens 204.

Similarly to the case of the first embodiment, the light source section 10 includes one or a plurality of semiconductor laser diodes, for example. The light source section 10 emits a pulsed laser beam L1 having a predetermined time width at a predetermined light emission period. Furthermore, the light source section 10 emits the laser beam L1 having a time width of 1 nanosecond at a rate of 1 gigahertz (GHz), for example.

Furthermore, the light receiving device 20 has a configuration similar to that of the light receiving device exemplified in the first embodiment, specifically, any of the light receiving devices according to the individual implementation examples of the first embodiment. Therefore, detailed description is omitted here. Note that the light receiving section 22 of the light receiving device 20 has a structure in which the pixels 60 exemplified in the first embodiment are arranged in the vertical direction (corresponding to the row direction), for example. That is, the light receiving section 32 can be formed with some rows (one row or several rows) of the SPAD array section 221 depicted in FIG. 4, for example.

### 2-2. Action and Effect

As described above, according to the second embodiment, by using any of the light receiving devices 20 according to the individual implementation examples of the first embodiment as the light receiving device in the scan-type distance measuring device, it is possible to obtain the action and effects similar to those of the first embodiment. In this manner, the technology according to the present disclosure can be applied not only to the flash-type distance measuring device but also to the scan-type distance measuring device.

The embodiments of the present disclosure have been described above. However, the technical scope of the present disclosure is not limited to the above-described embodiments, and various modifications can be made without departing from the scope of the present disclosure. Moreover, it is allowable to combine the components across different embodiments and modifications as appropriate.

The effects described in individual embodiments of the present specification are merely examples, and thus, there may be other effects, not limited to the exemplified effects.

### 3. Application Examples

The technology according to the present disclosure is applicable to various products. For example, the technology according to the present disclosure may be applied to devices mounted on any of mobile body such as automobiles, electric vehicles, hybrid electric vehicles, motorcycles, bicycles, personal mobility, airplanes, drones, ships, robots, construction machines, agricultural machines (tractors).

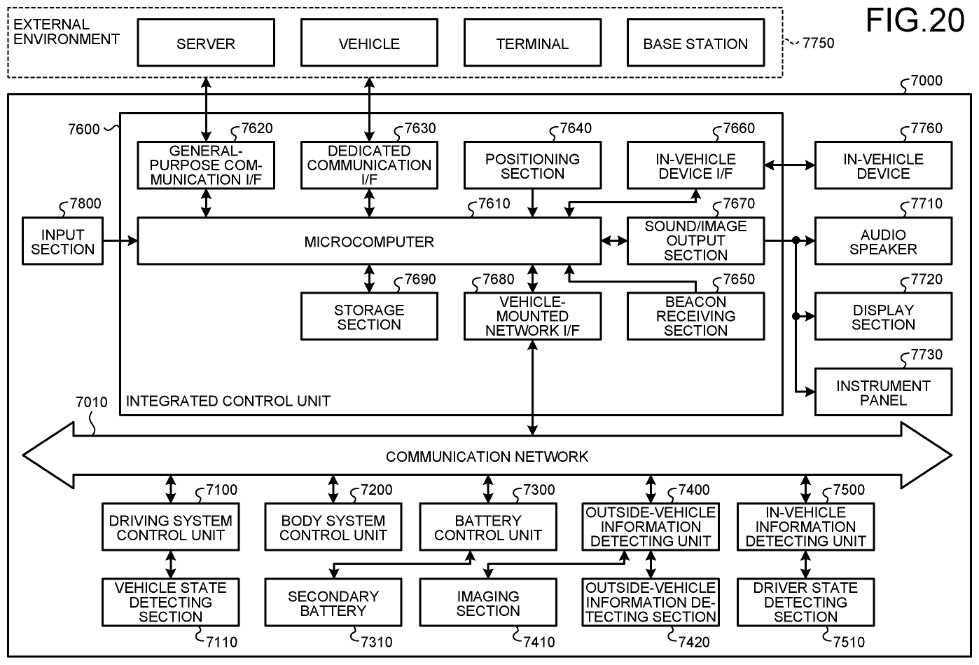

FIG. 20 is a block diagram depicting an example of schematic configuration of a vehicle control system 7000 as an example of a mobile body control system to which the technology according to an embodiment of the present disclosure can be applied. The vehicle control system 7000 includes a plurality of electronic control units connected to each other via a communication network 7010. In the example depicted in FIG. 20, the vehicle control system 7000 includes a driving system control unit 7100, a body system control unit 7200, a battery control unit 7300, an outside-vehicle information detecting unit 7400, an in-vehicle information detecting unit 7500, and an integrated control unit 7600. The communication network 7010 connecting the plurality of control units to each other may, for example, be a vehicle-mounted communication network compliant with an arbitrary standard such as controller area network (CAN), local interconnect network (LIN), local area network (LAN), FlexRay (registered trademark), or the like.

Each of the control units includes: a microcomputer that performs arithmetic processing according to various kinds of programs; a storage section that stores the programs executed by the microcomputer, parameters used for various kinds of operations, or the like; and a driving circuit that drives various kinds of control target devices. Each of the control units further includes: a network interface (I/F) for performing communication with other control units via the communication network 7010; and a communication I/F for performing communication with a device, a sensor, or the like within and without the vehicle by wire communication or radio communication. A functional configuration of the integrated control unit 7600 illustrated in FIG. 20 includes a microcomputer 7610, a general-purpose communication I/F 7620, a dedicated communication I/F 7630, a positioning section 7640, a beacon receiving section 7650, an in-vehicle device I/F 7660, a sound/image output section 7670, a vehicle-mounted network I/F 7680, and a storage section 7690. The other control units similarly include a microcomputer, a communication I/F, a storage section, and the like.

The driving system control unit 7100 controls the operation of devices related to the driving system of the vehicle in accordance with various kinds of programs. For example, the driving system control unit 7100 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like. The driving system control unit 7100 may have a function as a control device of an antilock brake system (ABS), electronic stability control (ESC), or the like.

The driving system control unit 7100 is connected with a vehicle state detecting section 7110. The vehicle state detecting section 7110, for example, includes at least one of a gyro sensor that detects the angular velocity of axial rotational movement of a vehicle body, an acceleration sensor that detects the acceleration of the vehicle, and sensors for detecting an amount of operation of an accelerator pedal, an amount of operation of a brake pedal, the steering angle of a steering wheel, an engine speed or the rotational speed of wheels, and the like. The driving system control unit 7100 performs arithmetic processing using a signal input from the vehicle state detecting section 7110, and controls the internal combustion engine, the driving motor, an electric power steering device, the brake device, and the like.

The body system control unit 7200 controls the operation of various kinds of devices provided to the vehicle body in accordance with various kinds of programs. For example, the body system control unit 7200 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 7200. The body system control unit 7200 receives these input radio waves or signals, and controls a door lock device, the power window device, the lamps, or the like of the vehicle.

The battery control unit 7300 controls a secondary battery 7310, which is a power supply source for the driving motor, in accordance with various kinds of programs. For example, the battery control unit 7300 is supplied with information about a battery temperature, a battery output voltage, an amount of charge remaining in the battery, or the like from a battery device including the secondary battery 7310. The battery control unit 7300 performs arithmetic processing using these signals, and performs control for regulating the temperature of the secondary battery 7310 or controls a cooling device provided to the battery device or the like.

The outside-vehicle information detecting unit 7400 detects information about the outside of the vehicle including the vehicle control system 7000. For example, the outside-vehicle information detecting unit 7400 is connected with at least one of an imaging section 7410 and an outside-vehicle information detecting section 7420. The imaging section 7410 includes at least one of a time-of-flight (ToF) camera, a stereo camera, a monocular camera, an infrared camera, and other cameras. The outside-vehicle information detecting section 7420, for example, includes at least one of an environmental sensor for detecting current atmospheric conditions or weather conditions and a peripheral information detecting sensor for detecting another vehicle, an obstacle, a pedestrian, or the like on the periphery of the vehicle including the vehicle control system 7000.

The environmental sensor, for example, may be at least one of a rain drop sensor detecting rain, a fog sensor detecting a fog, a sunshine sensor detecting a degree of sunshine, and a snow sensor detecting a snowfall. The peripheral information detecting sensor may be at least one of an ultrasonic sensor, a radar device, and a LIDAR device (Light detection and Ranging device, or Laser imaging detection and ranging device). Each of the imaging section 7410 and the outside-vehicle information detecting section 7420 may be provided as an independent sensor or device, or may be provided as a device in which a plurality of sensors or devices are integrated.

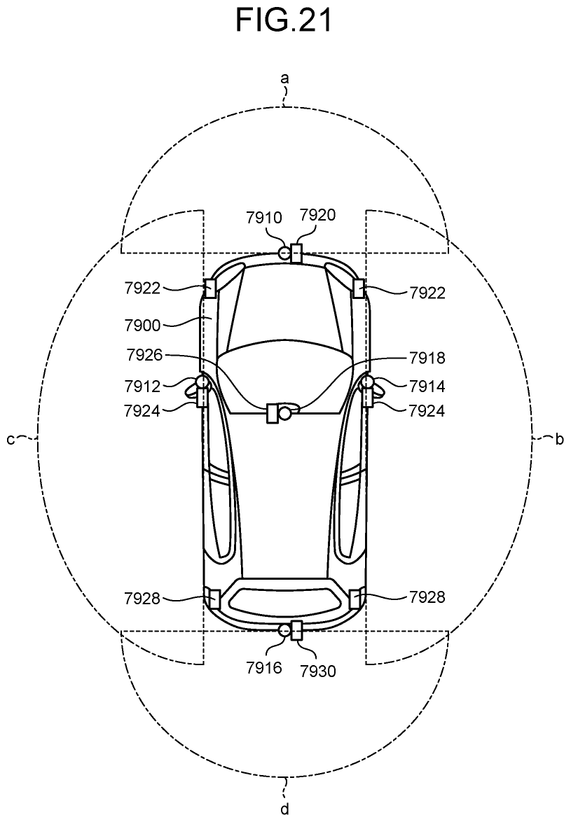

FIG. 21 depicts an example of installation positions of the imaging section 7410 and the outside-vehicle information detecting section 7420. Imaging sections 7910, 7912, 7914, 7916, and 7918 are, for example, disposed at at least one of positions on a front nose, sideview mirrors, a rear bumper, and a back door of the vehicle 7900 and a position on an upper portion of a windshield within the interior of the vehicle. The imaging section 7910 provided to the front nose and the imaging section 7918 provided to the upper portion of the windshield within the interior of the vehicle obtain mainly an image of the front of the vehicle 7900. The imaging sections 7912 and 7914 provided to the sideview mirrors obtain mainly an image of the sides of the vehicle 7900. The imaging section 7916 provided to the rear bumper or the back door obtains mainly an image of the rear of the vehicle 7900. The imaging section 7918 provided to the upper portion of the windshield within the interior of the vehicle is used mainly to detect a preceding vehicle, a pedestrian, an obstacle, a signal, a traffic sign, a lane, or the like.

Incidentally, FIG. 21 depicts an example of photographing ranges of the respective imaging sections 7910, 7912, 7914, and 7916. An imaging range a represents the imaging range of the imaging section 7910 provided to the front nose. Imaging ranges b and c respectively represent the imaging ranges of the imaging sections 7912 and 7914 provided to the sideview mirrors. An imaging range d represents the imaging range of the imaging section 7916 provided to the rear bumper or the back door. A bird's-eye image of the vehicle 7900 as viewed from above can be obtained by superimposing image data imaged by the imaging sections 7910, 7912, 7914, and 7916, for example.

Outside-vehicle information detecting sections 7920, 7922, 7924, 7926, 7928, and 7930 provided to the front, rear, sides, and corners of the vehicle 7900 and the upper portion of the windshield within the interior of the vehicle may be, for example, an ultrasonic sensor or a radar device. The outside-vehicle information detecting sections 7920, 7926, and 7930 provided to the front nose of the vehicle 7900, the rear bumper, the back door of the vehicle 7900, and the upper portion of the windshield within the interior of the vehicle may be a LIDAR device, for example. These outside-vehicle information detecting sections 7920 to 7930 are used mainly to detect a preceding vehicle, a pedestrian, an obstacle, or the like.

Returning to FIG. 20, the description will be continued. The outside-vehicle information detecting unit 7400 makes the imaging section 7410 image an image of the outside of the vehicle, and receives imaged image data. In addition, the outside-vehicle information detecting unit 7400 receives detection information from the outside-vehicle information detecting section 7420 connected to the outside-vehicle information detecting unit 7400. In a case where the outside-vehicle information detecting section 7420 is an ultrasonic sensor, a radar device, or a LIDAR device, the outside-vehicle information detecting unit 7400 transmits an ultrasonic wave, an electromagnetic wave, or the like, and receives information of a received reflected wave. On the basis of the received information, the outside-vehicle information detecting unit 7400 may perform processing of detecting an object such as a human, a vehicle, an obstacle, a sign, a character on a road surface, or the like, or processing of detecting a distance thereto. The outside-vehicle information detecting unit 7400 may perform environment recognition processing of recognizing a rainfall, a fog, road surface conditions, or the like on the basis of the received information. The outside-vehicle information detecting unit 7400 may calculate a distance to an object outside the vehicle on the basis of the received information.

In addition, on the basis of the received image data, the outside-vehicle information detecting unit 7400 may perform image recognition processing of recognizing a human, a vehicle, an obstacle, a sign, a character on a road surface, or the like, or processing of detecting a distance thereto. The outside-vehicle information detecting unit 7400 may subject the received image data to processing such as distortion correction, alignment, or the like, and combine the image data imaged by a plurality of different imaging sections 7410 to generate a bird's-eye image or a panoramic image. The outside-vehicle information detecting unit 7400 may perform viewpoint conversion processing using the image data imaged by the imaging section 7410 including the different imaging parts.

The in-vehicle information detecting unit 7500 detects information about the inside of the vehicle. The in-vehicle information detecting unit 7500 is, for example, connected with a driver state detecting section 7510 that detects the state of a driver. The driver state detecting section 7510 may include a camera that images the driver, a biosensor that detects biological information of the driver, a microphone that collects sound within the interior of the vehicle, or the like. The biosensor is, for example, disposed in a seat surface, the steering wheel, or the like, and detects biological information of an occupant sitting in a seat or the driver holding the steering wheel. On the basis of detection information input from the driver state detecting section 7510, the in-vehicle information detecting unit 7500 may calculate a degree of fatigue of the driver or a degree of concentration of the driver, or may determine whether the driver is dozing. The in-vehicle information detecting unit 7500 may subject an audio signal obtained by the collection of the sound to processing such as noise canceling processing or the like.

The integrated control unit 7600 controls general operation within the vehicle control system 7000 in accordance with various kinds of programs. The integrated control unit 7600 is connected with an input section 7800. The input section 7800 is implemented by a device capable of input operation by an occupant, such, for example, as a touch panel, a button, a microphone, a switch, a lever, or the like. The integrated control unit 7600 may be supplied with data obtained by voice recognition of voice input through the microphone. The input section 7800 may, for example, be a remote control device using infrared rays or other radio waves, or an external connecting device such as a mobile telephone, a personal digital assistant (PDA), or the like that supports operation of the vehicle control system 7000. The input section 7800 may be, for example, a camera. In that case, an occupant can input information by gesture. Alternatively, data may be input which is obtained by detecting the movement of a wearable device that an occupant wears. Further, the input section 7800 may, for example, include an input control circuit or the like that generates an input signal on the basis of information input by an occupant or the like using the above-described input section 7800, and which outputs the generated input signal to the integrated control unit 7600. An occupant or the like inputs various kinds of data or gives an instruction for processing operation to the vehicle control system 7000 by operating the input section 7800.

The storage section 7690 may include a read only memory (ROM) that stores various kinds of programs executed by the microcomputer and a random access memory (RAM) that stores various kinds of parameters, operation results, sensor values, or the like. In addition, the storage section 7690 may be implemented by a magnetic storage device such as a hard disc drive (HDD) or the like, a semiconductor storage device, an optical storage device, a magneto-optical storage device, or the like.

The general-purpose communication I/F 7620 is a communication I/F used widely, which communication I/F mediates communication with various apparatuses present in an external environment 7750. The general-purpose communication I/F 7620 may implement a cellular communication protocol such as global system for mobile communications (GSM (registered trademark)), worldwide interoperability for microwave access (WiMAX (registered trademark)), long term evolution (LTE (registered trademark)), LTE-advanced (LTE-A), or the like, or another wireless communication protocol such as wireless LAN (referred to also as wireless fidelity (Wi-Fi (registered trademark)), Bluetooth (registered trademark), or the like. The general-purpose communication I/F 7620 may, for example, connect to an apparatus (for example, an application server or a control server) present on an external network (for example, the Internet, a cloud network, or a company-specific network) via a base station or an access point. In addition, the general-purpose communication I/F 7620 may connect to a terminal present in the vicinity of the vehicle (which terminal is, for example, a terminal of the driver, a pedestrian, or a store, or a machine type communication (MTC) terminal) using a peer to peer (P2P) technology, for example.

The dedicated communication I/F 7630 is a communication I/F that supports a communication protocol developed for use in vehicles. The dedicated communication I/F 7630 may implement a standard protocol such, for example, as wireless access in vehicle environment (WAVE), which is a combination of institute of electrical and electronic engineers (IEEE) 802.11p as a lower layer and IEEE 1609 as a higher layer, dedicated short range communications (DSRC), or a cellular communication protocol. The dedicated communication I/F 7630 typically carries out V2X communication as a concept including one or more of communication between a vehicle and a vehicle (Vehicle to Vehicle), communication between a road and a vehicle (Vehicle to Infrastructure), communication between a vehicle and a home (Vehicle to Home), and communication between a pedestrian and a vehicle (Vehicle to Pedestrian).

The positioning section 7640, for example, performs positioning by receiving a global navigation satellite system (GNSS) signal from a GNSS satellite (for example, a GPS signal from a global positioning system (GPS) satellite), and generates positional information including the latitude, longitude, and altitude of the vehicle. Incidentally, the positioning section 7640 may identify a current position by exchanging signals with a wireless access point, or may obtain the positional information from a terminal such as a mobile telephone, a personal handyphone system (PHS), or a smart phone that has a positioning function.

The beacon receiving section 7650, for example, receives a radio wave or an electromagnetic wave transmitted from a radio station installed on a road or the like, and thereby obtains information about the current position, congestion, a closed road, a necessary time, or the like. Incidentally, the function of the beacon receiving section 7650 may be included in the dedicated communication I/F 7630 described above.

The in-vehicle device I/F 7660 is a communication interface that mediates connection between the microcomputer 7610 and various in-vehicle devices 7760 present within the vehicle. The in-vehicle device I/F 7660 may establish wireless connection using a wireless communication protocol such as wireless LAN, Bluetooth (registered trademark), near field communication (NFC), or wireless universal serial bus (WUSB). In addition, the in-vehicle device I/F 7660 may establish wired connection by universal serial bus (USB), high-definition multimedia interface (HDMI (registered trademark)), mobile high-definition link (MHL), or the like via a connection terminal (and a cable if necessary) not depicted in the figures. The in-vehicle devices 7760 may, for example, include at least one of a mobile device and a wearable device possessed by an occupant and an information device carried into or attached to the vehicle. The in-vehicle devices 7760 may also include a navigation device that searches for a path to an arbitrary destination. The in-vehicle device I/F 7660 exchanges control signals or data signals with these in-vehicle devices 7760.

The vehicle-mounted network I/F 7680 is an interface that mediates communication between the microcomputer 7610 and the communication network 7010. The vehicle-mounted network I/F 7680 transmits and receives signals or the like in conformity with a predetermined protocol supported by the communication network 7010.

The microcomputer 7610 of the integrated control unit 7600 controls the vehicle control system 7000 in accordance with various kinds of programs on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. For example, the microcomputer 7610 may calculate a control target value for the driving force generating device, the steering mechanism, or the braking device on the basis of the obtained information about the inside and outside of the vehicle, and output a control command to the driving system control unit 7100. For example, the microcomputer 7610 may perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like. In addition, the microcomputer 7610 may perform cooperative control intended for automated driving, which makes the vehicle to travel automatedly without depending on the operation of the driver, or the like, by controlling the driving force generating device, the steering mechanism, the braking device, or the like on the basis of the obtained information about the surroundings of the vehicle.

The microcomputer 7610 may generate three-dimensional distance information between the vehicle and an object such as a surrounding structure, a person, or the like, and generate local map information including information about the surroundings of the current position of the vehicle, on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. In addition, the microcomputer 7610 may predict danger such as collision of the vehicle, approaching of a pedestrian or the like, an entry to a closed road, or the like on the basis of the obtained information, and generate a warning signal. The warning signal may, for example, be a signal for producing a warning sound or lighting a warning lamp.

The sound/image output section 7670 transmits an output signal of at least one of a sound and an image to an output device capable of visually or auditorily notifying information to an occupant of the vehicle or the outside of the vehicle. In the example of FIG. 20, an audio speaker 7710, a display section 7720, and an instrument panel 7730 are illustrated as the output device. The display section 7720 may, for example, include at least one of an on-board display and a head-up display. The display section 7720 may have an augmented reality (AR) display function. The output device may be other than these devices, and may be another device such as headphones, a wearable device such as an eyeglass type display worn by an occupant or the like, a projector, a lamp, or the like. In a case where the output device is a display device, the display device visually displays results obtained by various kinds of processing performed by the microcomputer 7610 or information received from another control unit in various forms such as text, an image, a table, a graph, or the like. In addition, in a case where the output device is an audio output device, the audio output device converts an audio signal constituted of reproduced audio data or sound data or the like into an analog signal, and auditorily outputs the analog signal.

Incidentally, at least two control units connected to each other via the communication network 7010 in the example depicted in FIG. 20 may be integrated into one control unit. Alternatively, each individual control unit may include a plurality of control units. Further, the vehicle control system 7000 may include another control unit not depicted in the figures. In addition, part or the whole of the functions performed by one of the control units in the above description may be assigned to another control unit. That is, predetermined arithmetic processing may be performed by any of the control units as long as information is transmitted and received via the communication network 7010. Similarly, a sensor or a device connected to one of the control units may be connected to another control unit, and a plurality of control units may mutually transmit and receive detection information via the communication network 7010.

Note that a computer program for implementation of each function of the distance measuring device 1 according to each embodiment (each implementation example) can be installed on any control unit or the like. Furthermore, it is also possible to provide a computer-readable recording medium storing such a computer program. Examples of the recording medium include a magnetic disk, an optical disk, a magneto-optical disk, flash memory, or the like. Furthermore, the computer program described above may be distributed via a network, for example, without using a recording medium.

In the vehicle control system 7000 described above, the distance measuring device 1 according to each embodiment (each implementation example) described with reference to FIG. 1 and the like can be applied to the integrated control unit 7600 of the application example illustrated in FIG. 20. For example, components as a part of the light receiving device 20 of the distance measuring device 1 (such as the control section 21, the selecting section 23, the addition section 24, the histogram processing section 25, the computing section 26, and the external output interface 27) correspond to the microcomputer 7610, the storage section 7690, and the vehicle-mounted network I/F 7680 of the integrated control unit 7600. However, the configuration is not limited thereto, and the vehicle control system 7000 may correspond to the host 30 in FIG. 1.

Furthermore, at least some components of the distance measuring device 1 according to each embodiment (each implementation example) described with reference to FIG. 1 and the like may be implemented in a module (for example, an integrated circuit module formed with one die) for the integrated control unit 7600 depicted in FIG. 20. Alternatively, the distance measuring device 1 according to each embodiment (each implementation example) described with reference to FIG. 1 and the like may be implemented by a plurality of control units of the vehicle control system 7000 depicted in FIG. 20.

Hereinabove, an example of the vehicle control system to which the technology according to the present disclosure is applicable has been described. In the technology according to the present disclosure, for example, in a case where the imaging section 7410 includes a ToF camera (ToF sensor), it is possible use the distance measuring device 1 according to each embodiment (each implementation example), specifically, the light receiving device 20 in particular, as the ToF camera, among the components described above. With the light receiving device 20 installed as the ToF camera of the distance measuring device 1, it is possible to build a vehicle control system capable of achieving circuit scale reduction and power reduction, for example.

### 4. Supplementary Notes

Note that the present technique can also have the following configurations.

(1)

A light receiving device comprising:
a light receiving section including a plurality of photon-counting light receiving elements that receives reflected light from a distance measurement target based on irradiation pulsed light from a light source section;
a selecting section that selects individual detection values of the plurality of light receiving elements at a predetermined time;
an addition section that generates 2^{N}−1 binary values (N being a positive integer) from the individual detection values of the plurality of light receiving elements at the predetermined time selected by the selecting section and that calculates an N-bit pixel value by adding up all the 2^{N}−1 binary values; and
a computing section that performs computation related to distance measurement using the N-bit pixel value calculated by the addition section.

(2)

The light receiving device according to (1),
wherein the selecting section selects individual detection values of the 2^{N}−1 light receiving elements at the predetermined time.

(3)

The light receiving device according to (2),
wherein the selecting section selects the individual detection values of the 2^{N}−1 light receiving elements at the predetermined time from a rectangular region in which the number of light receiving elements is 2^{N}−1 in the light receiving section.

(4)

The light receiving device according to (2),
wherein the selecting section selects the individual detection values of the 2^{N}−1 light receiving elements at the predetermined time from a rectangular region in which the number of light receiving elements is 2^{M}−1 or more (M being a positive integer larger than N) in the light receiving section.

(5)

The light receiving device according to (4),
wherein the selecting section selects the individual detection values of the 2^{N}−1 light receiving elements at the predetermined time from a rectangular region in which the number of light receiving elements is 2^{M}−1 or more in the light receiving section by using a mask that validates the individual detection values of the 2^{N}−1 light receiving elements at the predetermined time.

(6)

The light receiving device according to (1),
wherein the selecting section selects individual detection values of 2^{M}−1 or more of the light receiving elements at the predetermined time (M being a positive integer larger than N), and
the addition section adds up the individual binary values of 2^{M}−1 or more of the light receiving elements selected by the selecting section, and calculates the N-bit pixel value by setting an added-up value that is 2^{N}−1 or more to 2^{N}−1.

(7)

The light receiving device according to (1),
wherein the addition section generates 2^{N}−1 binary values by setting the number of lines of output that indicates 1 when a predetermined number of the light receiving elements at the predetermined time have simultaneously received light to 2^{N}−1, and calculates the N-bit pixel value by adding up all the 2^{N}−1 binary values.

(8)

The light receiving device according to (1),
wherein the addition section generates 2^{N}−1 binary values by setting the number of lines of output that indicates 1 when one or more of a predetermined number of the light receiving elements at the predetermined time have received light to 2^{N}−1, and calculates the N-bit pixel value by adding up all the 2^{N}−1 binary values.

(9)

The light receiving device according to (1),
wherein the addition section includes:
a first addition section that calculates the N-bit pixel value by adding up all the 2^{N}−1 binary values; and
a second addition section that adds up a plurality of the N-bit pixel values calculated by the first addition section to calculate a macro-pixel value, and
the computing section performs the computation related to distance measurement using the macro-pixel value calculated by the second addition section.

(10)

The light receiving device according to any one of (1) to (8), further comprising
memory that stores a histogram of the N-bit pixel values calculated by the addition section,
wherein the computing section performs the computation related to distance measurement using the histogram stored in the memory.

(11)

The light receiving device according to (9), further comprising
memory that stores a histogram of the macro-pixel value calculated by the second addition section,
wherein the computing section performs the computation related to distance measurement using the histogram stored in the memory.

(12)

The light receiving device according to any one of (1) to (11),
wherein the light receiving element is an avalanche photodiode that operates in a Geiger mode.

(13)

A distance measuring device comprising:
a light source section that irradiates a distance measurement target with pulsed light; and
a light receiving device that receives reflected light from the distance measurement target based on irradiation pulsed light from the light source section,
wherein the light receiving device includes:
a light receiving section including a plurality of photon-counting light receiving elements that receives reflected light from a distance measurement target;
a selecting section that selects individual detection values of the plurality of light receiving elements at a predetermined time;
an addition section that generates 2^{N}−1 binary values (N being a positive integer) from the individual detection values of the plurality of light receiving elements at the predetermined time selected by the selecting section and that calculates an N-bit pixel value by adding up all the 2^{N}−1 binary values; and
a computing section that performs computation related to distance measurement using the N-bit pixel value calculated by the addition section.

(14)

A signal processing method to be used by a light receiving device, the method comprising:
receiving, by a light receiving section including a plurality of photon-counting light receiving elements, reflected light from a distance measurement target based on irradiation pulsed light from a light source section;
selecting individual detection values of the plurality of light receiving elements at a predetermined time;
generating 2^{N}−1 binary values (N being a positive integer) from the individual detection values of the plurality of light receiving elements at the predetermined time selected and calculating an N-bit pixel value by adding up all the 2^{N}−1 binary values; and
performing computation related to distance measurement using the N-bit pixel value calculated.

(15)

A distance measuring device including the light receiving device according to any one of (1) to (12).

(16)

A signal processing method used by a light receiving device that performs signal processing related to the light receiving device according to any one of (1) to (12).

### REFERENCE SIGNS LIST

1 DISTANCE MEASURING DEVICE
10 LIGHT SOURCE SECTION
20 LIGHT RECEIVING DEVICE
21 CONTROL SECTION
22 LIGHT RECEIVING SECTION
23 SELECTING SECTION
24 ADDITION SECTION
24a SPAD ADDITION SECTION
24b MACRO-PIXEL ADDITION SECTION
25 HISTOGRAM PROCESSING SECTION
25a MEMORY
26 COMPUTING SECTION
27 EXTERNAL OUTPUT INTERFACE
30 HOST
32 LIGHT RECEIVING SECTION
40 DISTANCE MEASUREMENT TARGET
50 SPAD PIXEL
51 SPAD ELEMENT
52 READ CIRCUIT
60 PIXEL
90 OBJECT
200 CONTROL DEVICE
201 CONDENSER LENS
202 HALF MIRROR
203 MICROMIRROR
204 LIGHT RECEIVING LENS
205 SCANNING SECTION
221 SPAD ARRAY SECTION
222 TIMING CONTROL SECTION
223 DRIVING SECTION
224 OUTPUT SECTION
241 PULSE SHAPING SECTION
242 LIGHT RECEPTION NUMBER COUNTER

1. A light receiving device comprising:
a light receiving section including a plurality of photon-counting light receiving elements that receives reflected light from a distance measurement target based on irradiation pulsed light from a light source section;
a selecting section that selects individual detection values of the plurality of light receiving elements at a predetermined time;
an addition section that generates 2^{N}−1 binary values (N being a positive integer) from the individual detection values of the plurality of light receiving elements at the predetermined time selected by the selecting section and that calculates an N-bit pixel value by adding up all the 2^{N}−1 binary values; and
a computing section that performs computation related to distance measurement using the N-bit pixel value calculated by the addition section.

2. The light receiving device according to claim 1,
wherein the selecting section selects individual detection values of the 2^{N}−1 light receiving elements at the predetermined time.

3. The light receiving device according to claim 2,
wherein the selecting section selects the individual detection values of the 2^{N}−1 light receiving elements at the predetermined time from a rectangular region in which the number of light receiving elements is 2^{N}−1 in the light receiving section.

4. The light receiving device according to claim 2,
wherein the selecting section selects the individual detection values of the 2^{N}−1 light receiving elements at the predetermined time from a rectangular region in which the number of light receiving elements is 2^{M}−1 or more (M being a positive integer larger than N) in the light receiving section.

5. The light receiving device according to claim 4,
wherein the selecting section selects the individual detection values of the 2^{N}−1 light receiving elements at the predetermined time from a rectangular region in which the number of light receiving elements is 2^{M}−1 or more in the light receiving section by using a mask that validates the individual detection values of the 2^{N}−1 light receiving elements at the predetermined time.

6. The light receiving device according to claim 1,
wherein the selecting section selects individual detection values of 2^{M}−1 or more of the light receiving elements at the predetermined time (M being a positive integer larger than N), and
the addition section adds up the individual binary values of 2^{M}−1 or more of the light receiving elements selected by the selecting section, and calculates the N-bit pixel value by setting an added-up value that is 2^{N}−1 or more to 2^{N}−1.

7. The light receiving device according to claim 1,
wherein the addition section generates 2^{N}−1 binary values by setting the number of lines of output that indicates 1 when a predetermined number of the light receiving elements at the predetermined time have simultaneously received light to 2^{N}−1, and calculates the N-bit pixel value by adding up all the 2^{N}−1 binary values.

8. The light receiving device according to claim 1,
wherein the addition section generates 2^{N}−1 binary values by setting the number of lines of output that indicates 1 when one or more of a predetermined number of the light receiving elements at the predetermined time have received light to 2^{N}−1, and calculates the N-bit pixel value by adding up all the 2^{N}−1 binary values.

9. The light receiving device according to claim 1,
wherein the addition section includes:
a first addition section that calculates the N-bit pixel value by adding up all the 2^{N}−1 binary values; and
a second addition section that adds up a plurality of the N-bit pixel values calculated by the first addition section to calculate a macro-pixel value, and
the computing section performs the computation related to distance measurement using the macro-pixel value calculated by the second addition section.

10. The light receiving device according to claim 1, further comprising
memory that stores a histogram of the N-bit pixel values calculated by the addition section,
wherein the computing section performs the computation related to distance measurement using the histogram stored in the memory.

11. The light receiving device according to claim 9, further comprising
memory that stores a histogram of the macro-pixel value calculated by the second addition section,
wherein the computing section performs the computation related to distance measurement using the histogram stored in the memory.

12. The light receiving device according to claim 1,
wherein the light receiving element is an avalanche photodiode that operates in a Geiger mode.

13. A distance measuring device comprising:
a light source section that irradiates a distance measurement target with pulsed light; and
a light receiving device that receives reflected light from the distance measurement target based on irradiation pulsed light from the light source section,
wherein the light receiving device includes:
a light receiving section including a plurality of photon-counting light receiving elements that receives reflected light from a distance measurement target;
a selecting section that selects individual detection values of the plurality of light receiving elements at a predetermined time;
an addition section that generates 2^{N}−1 binary values (N being a positive integer) from the individual detection values of the plurality of light receiving elements at the predetermined time selected by the selecting section and that calculates an N-bit pixel value by adding up all the 2^{N}−1 binary values; and
a computing section that performs computation related to distance measurement using the N-bit pixel value calculated by the addition section.

14. A signal processing method to be used by a light receiving device, the method comprising:
receiving, by a light receiving section including a plurality of photon-counting light receiving elements, reflected light from a distance measurement target based on irradiation pulsed light from a light source section;
selecting individual detection values of the plurality of light receiving elements at a predetermined time;
generating 2^{N}−1 binary values (N being a positive integer) from the individual detection values of the plurality of light receiving elements at the predetermined time selected and calculating an N-bit pixel value by adding up all the 2^{N}−1 binary values; and
performing computation related to distance measurement using the N-bit pixel value calculated.
